(19) United States
(12) Patent Application Publication
(10) Pub. No.: US 2026/0101542 A1
(43) Pub. Date: Apr. 9, 2026

(54) STRESS GENERATION IN STACKED NANOSHEET ARCHITECTURES

(71) Applicant: International Business Machines Corporation, Armonk, NY (US)

(72) Inventors: Shahrukh Khan, Sandy Hook, CT (US); Mohammad Hasanuzzaman, Niskayuna, NY (US); Biswanath Senapati, Mechanicville, NY (US); Utkarsh Bajpai, Delmar, NY (US); Jingyun Zhang, Albany, NY (US); Chen Zhang, Santa Clara, CA (US); Junli Wang, Slingerlands, NY (US); Tenko Yamashita, Schenectady, NY (US)

(21) Appl. No.: 18/909,291

(22) Filed: Oct. 8, 2024

(51) Int. Cl. H01L 29/78; H01L 21/822; H01L 21/8238; H01L 27/092; H01L 29/06; H01L 29/08; H01L 29/423; H01L 29/66; H01L 29/775; H01L 29/786

(52) U.S. Cl. CPC H10D 30/795; H10D 30/014; H10D 30/43; H10D 30/6735; H10D 30/6757; H10D 62/121; H10D 62/151; H10D 84/017; H10D 84/0188; H10D 84/038; H10D 84/856; H10D 88/01

(57) ABSTRACT

A vertically stacked 3D nanosheet field effect transistor component includes a bottom nanosheet device, a middle dielectric isolation region coupled to the bottom nanosheet device, and a top nanosheet device coupled to the middle dielectric isolation region. The middle dielectric isolation region can include at least one embedded stressor mechanically coupled to at least one of the bottom nanosheet device and the top nanosheet device that imparts an embedded stressor originated stress in at least one of the bottom nanosheet device and the top nanosheet device. At least one of the bottom nanosheet device and the top nanosheet device include at least one interlayer originated stress. The stress(es) impart device performance boost(s) for at least one of the bottom nanosheet device and the top nanosheet device.

### BACKGROUND

The present disclosure relates to the electrical, electronic, and computer fields. In particular, the present disclosure relates to components and methods for stress generation in stacked nanosheet architectures.

In stacked nanosheet CMOS architecture, intrinsic stress generation for device performance enhancement is important. Compared to industry 5 nm FinFET technology, intrinsic FET devices at a same W_{eff} fall short of performance. Although GAA Nanosheet provides superior electrostatics and W_{eff} scaling with the same physical footprint, at scaled nanosheet device dimensions, transfer of stress into the channel (for both NFET and PFET) is minimal.

### SUMMARY

Embodiments of the present disclosure include structures and fabrication methods for stress generation in stacked nanosheet architecture with dielectric isolation.

Embodiments of the present disclosure include a vertically stacked 3D nanosheet field effect transistor component. The component includes a bottom nanosheet device comprising a first bottom source/drain and a second bottom source/drain; a middle dielectric isolation region coupled to the bottom nanosheet device; and a top nanosheet device coupled to the middle dielectric isolation region, the top nanosheet device comprising a first top source/drain and a second top source/drain. The middle dielectric isolation region can include at least one embedded stressor mechanically coupled to at least one of the bottom nanosheet device and the top nanosheet device, wherein the at least one embedded stressor imparts an embedded stressor originated stress in at least one of the bottom nanosheet device and the top nanosheet device that imparts an embedded stressor originated force against at least one of the bottom nanosheet device and the top nanosheet device. At least one of the bottom nanosheet device and the top nanosheet device can include at least one interlayer originated stress that imparts at least one interlayer originated force against at least one of the bottom nanosheet device and the top nanosheet device.

Additional embodiments of the present disclosure include a method for forming a vertically stacked 3D nanosheet field effect transistor component. The method includes providing a vertically stacked nanosheet component including a bottom nanosheet component; a middle dielectric isolation region coupled to the bottom nanosheet component; and a top nanosheet component coupled to the middle dielectric isolation region. The method includes depositing an oxide/SiN liner on at least a portion of the middle dielectric isolation region. The method includes releasing selectively at least a portion of the middle dielectric isolation region to define an embedded stressor region. The method includes stripping the oxide/SiN liner. The method includes depositing an embedded stressor material at least within the embedded stressor region using atomic layer depositing.

Additional embodiments of the present disclosure include another method for forming a vertically stacked 3D nanosheet field effect transistor component. This method includes providing a vertically stacked nanosheet component including a bottom nanosheet component; a middle dielectric isolation region coupled to the bottom nanosheet component; and a top nanosheet component coupled to the middle dielectric isolation region. The method includes forming at least two recesses that extend through the top nanosheet component, the middle dielectric isolation region and the bottom nanosheet component. The method includes depositing a spin on glass coating. The method includes chemical mechanical polishing the spin on glass coating. The method includes etching the spin on glass coating back to form at least two recesses that extend down to beneath a top of the middle dielectric isolation region. The method includes depositing an oxide liner on the at least two recesses that extend down to beneath a top of the middle dielectric isolation region to protect the top nanosheet component. The method includes releasing at least a portion of the bottom nanosheet component to define at least one bottom interlayer stressor region. The method includes depositing at least one bottom sacrificial stressed dielectric to plug the at least one bottom interlayer stressor region. The method includes etching back the at least one bottom sacrificial stressed dielectric. The method includes etching away the oxide liner. The method includes releasing at least a portion of the top nanosheet component to define at least one top interlayer stressor region. The method includes depositing at least one top sacrificial stressed dielectric to plug the at least one top interlayer stressor region. The method includes etching back the at least one top sacrificial stressed dielectric. The method includes etching to indent both the at least one bottom sacrificial stressed dielectric and the at least one top sacrificial stressed dielectric. The method includes depositing at least one bottom inner spacer adjacent the at least one bottom sacrificial stressed dielectric and depositing at least one top inner spacer adjacent the at least one top sacrificial stressed dielectric. The method includes depositing at least two bottom source/drains adjacent the at least one bottom inner spacer and depositing at least two bottom dielectric plugs adjacent tops of the at least two bottom source/drains. The method includes depositing at least two top source/drains adjacent the at least one top inner spacer and depositing at least two top dielectric plug adjacent tops of the at least two top source/drains. The method includes forming at least two vias through the top nanosheet component, through the middle dielectric isolation region, and to a bottom of the bottom nanosheet component. The method includes removing both the at least one top sacrificial stressed dielectric and the at least one bottom sacrificial stressed dielectric, using the at least two vias. The method includes depositing a high K dielectric layer.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

FIG. 1 illustrates a flow diagram of an exemplary stressed middle dielectric isolation method that can be implemented in accordance with embodiments of the present disclosure.

FIGS. 2A-2B illustrate 2 views of an example of a component following the performance of a portion of the example method of FIG. 1, in accordance with embodiments of the present disclosure.

FIGS. 3A-B illustrate 2 views of an example of a component following the performance of a portion of the example method of FIG. 1, in accordance with embodiments of the present disclosure.

FIGS. 4A-4B illustrate 2 views of an example of a component following the performance of a portion of the example method of FIG. 1, in accordance with embodiments of the present disclosure.

FIGS. 5A-5B illustrate 2 views of an example of a component following the performance of a portion of the example method of FIG. 1, in accordance with embodiments of the present disclosure.

FIGS. 6A-6B illustrate 2 views of an example of a component following the performance of a portion of the example method of FIG. 1, in accordance with embodiments of the present disclosure.

FIGS. 7A-7B illustrate 2 views of an example of a component following the performance of a portion of the example method of FIG. 1, in accordance with embodiments of the present disclosure.

FIGS. 8A-8B illustrate 2 views of an example of a component following the performance of a portion of the example method of FIG. 1, in accordance with embodiments of the present disclosure.

FIGS. 9A-9D illustrate 4 views of an example of a component following the performance of a portion of the example method of FIG. 1, in accordance with embodiments of the present disclosure.

FIGS. 10A-10D illustrate 4 views of an example of a component following the performance of a portion of the example method of FIG. 1, in accordance with embodiments of the present disclosure.

FIGS. 11A-11D illustrate 4 views of an example of a component following the performance of a portion of the example method of FIG. 1, in accordance with embodiments of the present disclosure.

FIGS. 12A-12D illustrate 4 views of an example of a component following the performance of a portion of the example method of FIG. 1, in accordance with embodiments of the present disclosure.

FIGS. 13A-13D illustrate 4 views of an example of a component following the performance of a portion of the example method of FIG. 1, in accordance with embodiments of the present disclosure.

FIGS. 14A-14D illustrate 4 views of an example of a component following the performance of a portion of the example method of FIG. 1, in accordance with embodiments of the present disclosure.

FIGS. 15A-15D illustrate 4 views of an example of a component following the performance of a portion of the example method of FIG. 1, in accordance with embodiments of the present disclosure.

FIGS. 16A-16D illustrate 4 views of an example of a component following the performance of a portion of the example method of FIG. 1, in accordance with embodiments of the present disclosure.

FIGS. 17A-17D illustrate 4 views of an example of a component following the performance of a portion of the example method of FIG. 1, in accordance with embodiments of the present disclosure.

FIGS. 18A-18D illustrate 4 views of an example of a component following the performance of a portion of the example method of FIG. 1, in accordance with embodiments of the present disclosure.

FIGS. 19A-19D illustrate 4 views of an example of a component following the performance of a portion of the example method of FIG. 1, in accordance with embodiments of the present disclosure.

FIGS. 20A and 20B illustrate a flow diagram of an exemplary sacrificial stressed nanosheet interlayer method that can be implemented in accordance with embodiments of the present disclosure.

FIGS. 21A-21D illustrate 4 views of an example of a component following the performance of a portion of the example method of FIGS. 20-1 and 20-2, in accordance with embodiments of the present disclosure.

FIGS. 22A-22D illustrate 4 views of an example of a component following the performance of a portion of the example method of FIGS. 20-1 and 20-2, in accordance with embodiments of the present disclosure.

FIGS. 23A-23D illustrate 4 views of an example of a component following the performance of a portion of the example method of FIGS. 20-1 and 20-2, in accordance with embodiments of the present disclosure.

FIGS. 24A-24D illustrate 4 views of an example of a component following the performance of a portion of the example method of FIGS. 20-1 and 20-2, in accordance with embodiments of the present disclosure.

FIGS. 25A-25D illustrate 4 views of an example of a component following the performance of a portion of the example method of FIGS. 20-1 and 20-2, in accordance with embodiments of the present disclosure.

FIGS. 26A-26D illustrate 4 views of an example of a component following the performance of a portion of the example method of FIGS. 20-1 and 20-2, in accordance with embodiments of the present disclosure.

FIGS. 27A-27D illustrate 4 views of an example of a component following the performance of a portion of the example method of FIGS. 20-1 and 20-2, in accordance with embodiments of the present disclosure.

FIGS. 28A-28D illustrate 4 views of an example of a component following the performance of a portion of the example method of FIGS. 20-1 and 20-2, in accordance with embodiments of the present disclosure.

FIGS. 29A-29D illustrate 4 views of an example of a component following the performance of a portion of the example method of FIGS. 20-1 and 20-2, in accordance with embodiments of the present disclosure.

FIGS. 30A-30D illustrate 4 views of an example of a component following the performance of a portion of the example method of FIGS. 20-1 and 20-2, in accordance with embodiments of the present disclosure.

FIGS. 31A-31D illustrate 4 views of an example of a component following the performance of a portion of the example method of FIGS. 20-1 and 20-2, in accordance with embodiments of the present disclosure.

FIGS. 32A-32D illustrate 4 views of an example of a component following the performance of a portion of the example method of FIGS. 20-1 and 20-2, in accordance with embodiments of the present disclosure.

FIGS. 33A-33D illustrate 4 views of an example of a component following the performance of a portion of the example method of FIGS. 20-1 and 20-2, in accordance with embodiments of the present disclosure.

FIGS. 34A-34D illustrate 4 views of an example of a component following the performance of a portion of the example method of FIGS. 20-1 and 20-2, in accordance with embodiments of the present disclosure.

FIGS. 35A-35D illustrate 4 views of an example of a component following the performance of a portion of the example method of FIGS. 20-1 and 20-2, in accordance with embodiments of the present disclosure.

FIGS. 36A-36D illustrate 4 views of an example of a component following the performance of a portion of the example method of FIGS. 20-1 and 20-2, in accordance with embodiments of the present disclosure.

### DETAILED DESCRIPTION

Aspects of the present disclosure relate generally to the electrical, electronic, and computer fields. In particular, the present disclosure relates to semiconductor devices, especially read only memory. While the present disclosure is not necessarily limited to such applications, various aspects of the disclosure may be appreciated through a discussion of various examples using this context.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B”are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

The below-referenced U.S. Patent(s) and/or U.S. Patent Application(s) disclose embodiments that are useful for the purposes for which they are intended. The entire contents of U.S. Pat. Nos. 11,575,003; 10,249,739; and 8,492,208 are hereby expressly incorporated by reference herein for all purposes.

Stress generation without embedded stressors within channel has been elusive. Use of an embedded stressor, with High Ge % SiGe epi is one possible solution. Strained uniaxial or biaxial channel (strained SiGe channel with higher Ge % for PFET) is another possibility. However, in both cases, higher Ge % SiGe epi or strained channel formation is prone to defectivity and limiting. An innovation is required to externally transfer stress for stacked nanosheet CMOS based logic devices that closes the gap to industry 5 nm/4 nm based intrinsic FET performance.

Embodiments of the present disclosure include structures and methods of stress generation in stacked nanosheet architecture with dielectric isolation. Dielectric material of a first kind with compressive and/or tensile stress embedded in the middle dielectric isolation to separate the top-NS device from the bottom-NS device of a vertically stacked nanosheet FET. (This can be referred to as Middle Dielectric Isolation (MDI). This dielectric isolation (MDI) can impart device performance boost for either the top and/or bottom nanosheet device(s) of opposite polarity (NFET/PFET). Compressive stressed MDI boosts NFET device performance, Tensile stressed MDI boosts PFET device performance. This is applicable to both monolithic and bonded integration of stacked FET. Co-integration of dual stressed MDI can impart stress to both devices. Tuning the distance of MDI to unstrained channel can tune the boost performance.

Embodiments of the present disclosure include structures and methods of stress generation in stacked nanosheet architecture with sacrificial stressed nanosheet interlayers. Dielectric material of a first kind with either compressive or tensile stress is deposited as a sacrificial interlayer between nanosheets for the bottom device of a vertically stacked 3D nanosheet transistor. Dielectric material of a second kind with either tensile or compressive stress is deposited as a sacrificial interlayer between nanosheet for the top device of a vertically stacked 3D nanosheet transistor. The sacrificial stressed layers transfer compressive or tensile stress to unstrained nanosheets to impart device performance boost. The structure and method described is applicable to both monolithic and bonded integration of stacked FET. Co-integration of dual stressed interlayer can impart stress to both devices. Tuning of suspended layer thickness imparts additional performance gain.

Embodiments are applicable to stacked nanosheet FET technology. Embodiments are applicable to both monolithic & bonded integration of stacked FET. Embodiments are detectable with material/compositional analysis in tear-downs. Embodiments are detectable as a unique material of MDI vs. POR/presumptive flows that use MDI that is same as spacer material. Embodiments can include co-integration of tensile and compressive stressed MDI to impart both NFET/PFET boost. Embodiments can include co-integration of tensile and compressive stressed sacrificial nanosheet interlayer that imparts both NFET/PFET performance boost.

The processes, steps, and structures described below do not form a complete process flow for manufacturing integrated circuits. The disclosure can be practiced in conjunction with integrated circuit fabrication techniques currently used in the art, and only so much of the commonly practiced process steps are included as necessary for an understanding of the different examples of the present disclosure. Many of the figures represent cross sections of a portion of an integrated circuit during fabrication and are not drawn to scale, but instead are drawn so as to illustrate different illustrative features of the disclosure.

In general, the various processes for a semiconductor chip or micro-chip that will be packaged into an IC fall into three general categories, namely, deposition, removal/etching, and patterning/lithography.

Deposition is any process that grows, coats, or otherwise transfers a material onto the substrate. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the substrate surface that would otherwise require higher temperatures associated with conventional CVD. Energetic ion bombardment during PECVD deposition can also improve the film's electrical and mechanical properties.

Removal/etching is any process that removes material from the substrate. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on substrates. With RIE the plasma is generated under low pressure (vacuum) by an electromagnetic field. High-energy ions from the RIE plasma attack the substrate surface and react with it to remove material.

Patterning/lithography is the formation of three-dimensional relief images or patterns on the semiconductor substrate for subsequent transfer of the pattern to a layer arranged beneath the pattern. In semiconductor lithography, the patterns are formed by a light sensitive polymer called a photoresist.

The flowcharts and block diagrams in the Figures illustrate the architecture, functionality, and operation of possible implementations of systems and methods according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

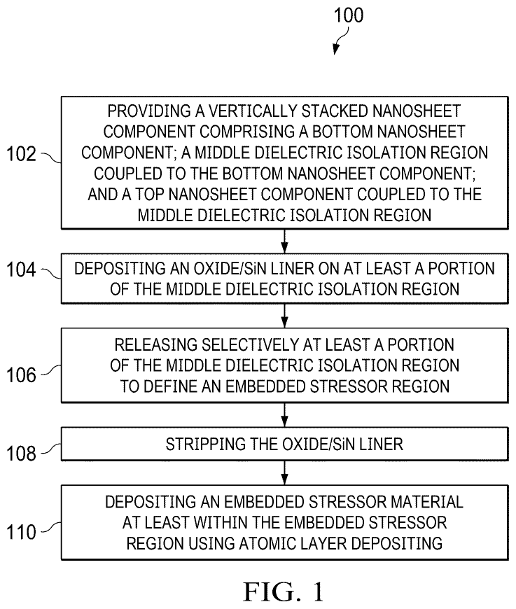

FIG. 1 shows a first flowchart 100 illustrating steps for forming an embodiment of a vertically stacked 3D nanosheet field effect transistor component. Step 102 includes providing a vertically stacked nanosheet component comprising a bottom nanosheet component; a middle dielectric isolation region coupled to the bottom nanosheet component; and a top nanosheet component coupled to the middle dielectric isolation region. Step 104 includes depositing an oxide/SiN liner on at least a portion of the middle dielectric isolation region. Step 106 includes releasing selectively at least a portion of the middle dielectric isolation region to define an embedded stressor region. Step 108 includes stripping the oxide/SiN liner. Step 110 includes depositing an embedded stressor material at least within the embedded stressor region using atomic layer depositing.

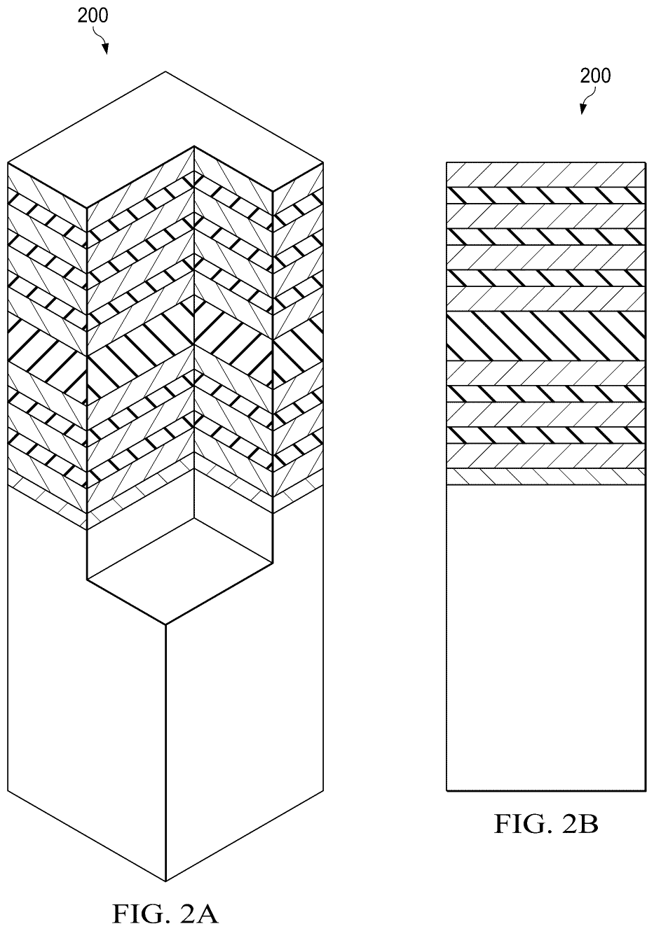

FIGS. 2A-2B show two views of a partially completed component 200. The partially completed component 200 includes structure formed by nanosheet epitaxy using sacrificial high silicon germanium e.g. 60% for middle dielectric isolation.

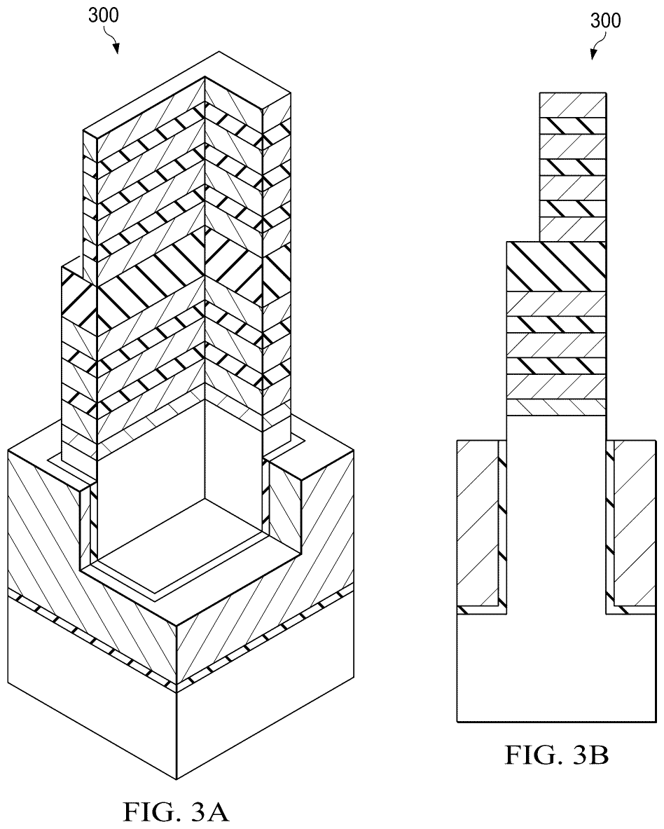

FIGS. 3A-3B show two views of a partially completed component 300. The partially completed component 300 includes structure formed by nano sheet stack patterning.

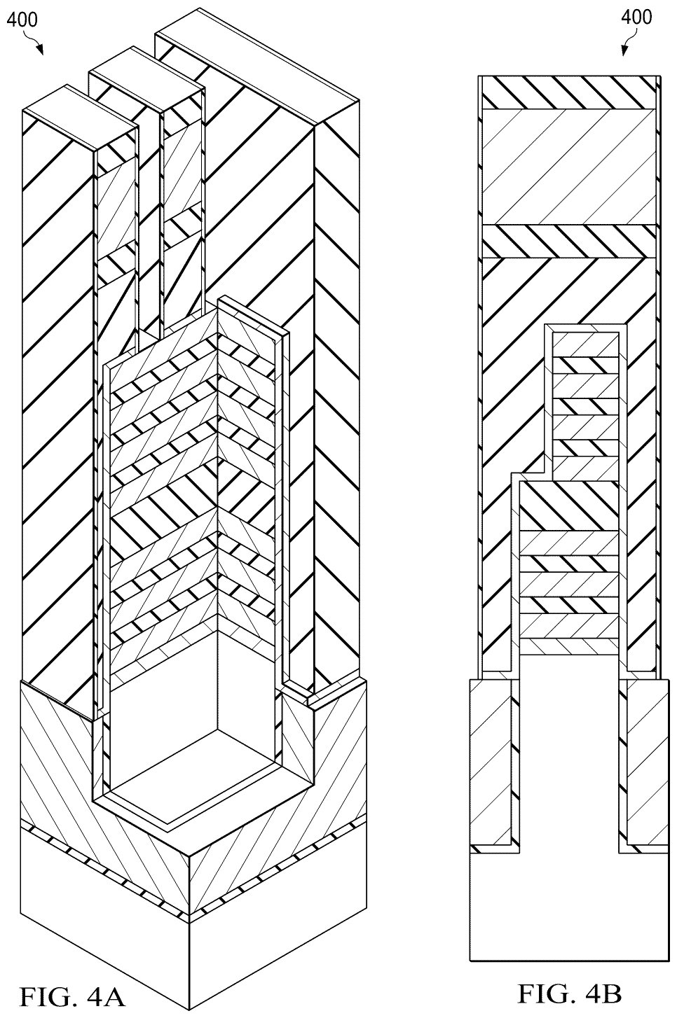

FIGS. 4A-4B show two views of a partially completed component 400. The partially completed component 400 includes structure formed by dummy PC patterning.

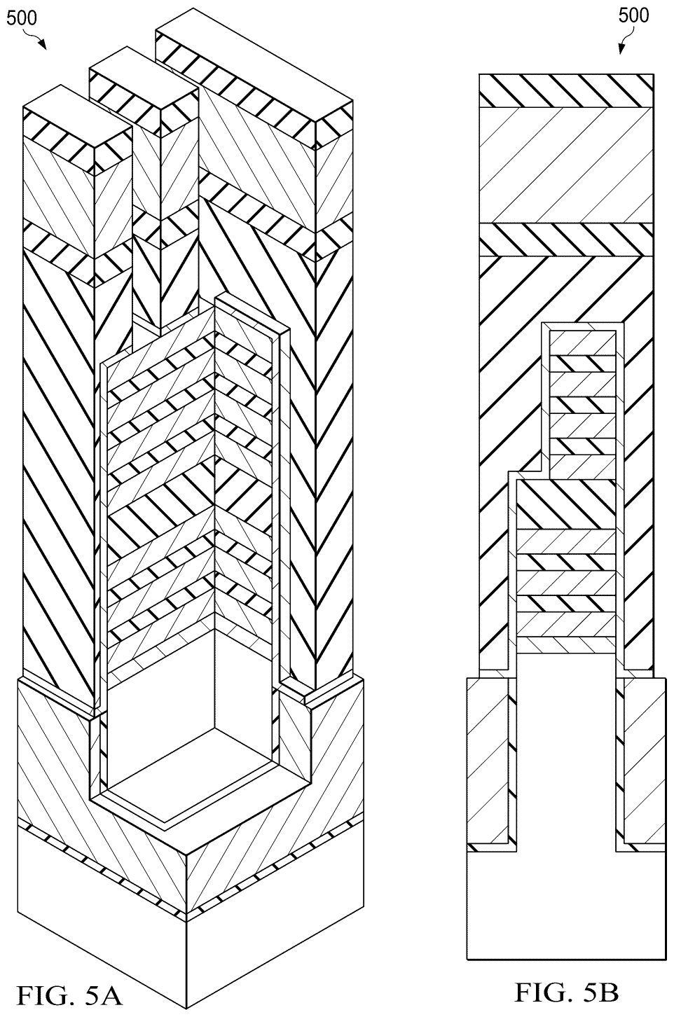

FIGS. 5A-5B show two views of a partially completed component 500. The partially completed component 500 includes structure formed by oxide/SiN line deposition pre-MDI release.

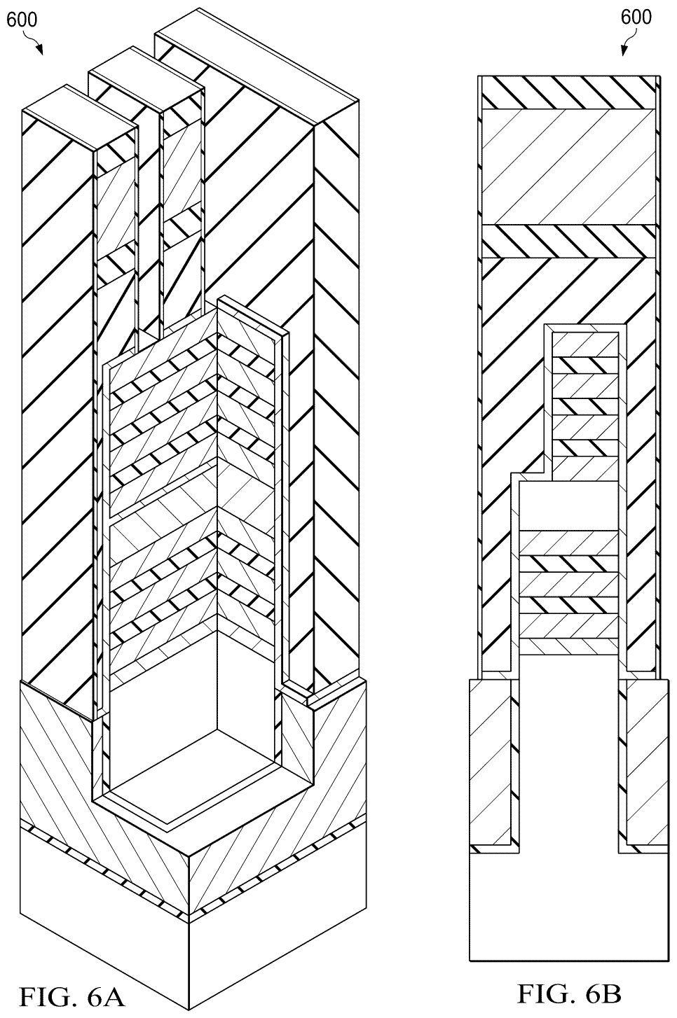

FIGS. 6A-6B show two views of a partially completed component 600. The partially completed component 600 includes structure formed by selective MDI release.

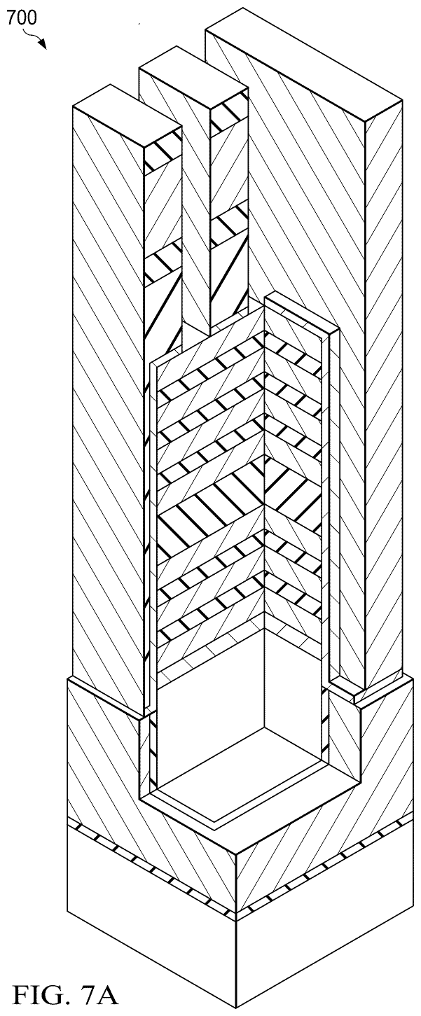

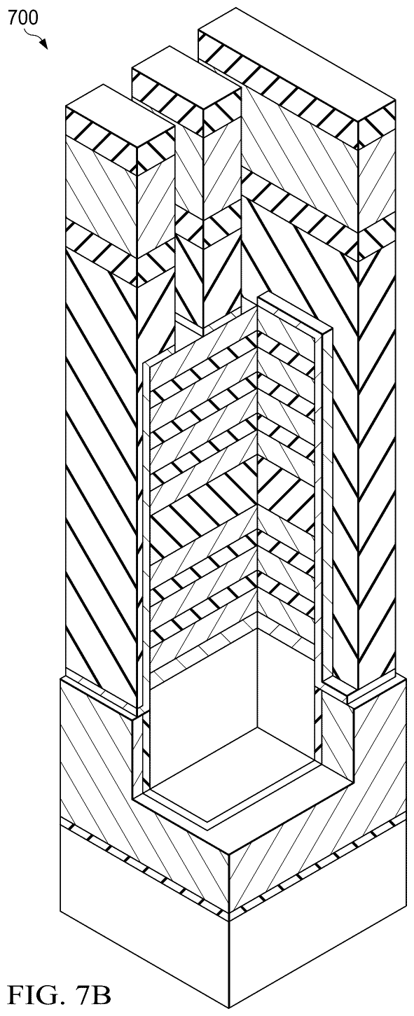

FIGS. 7A-7B show two views of a partially completed component 700. The partially completed component 700 includes structure formed by oxide/SiN liner strip.

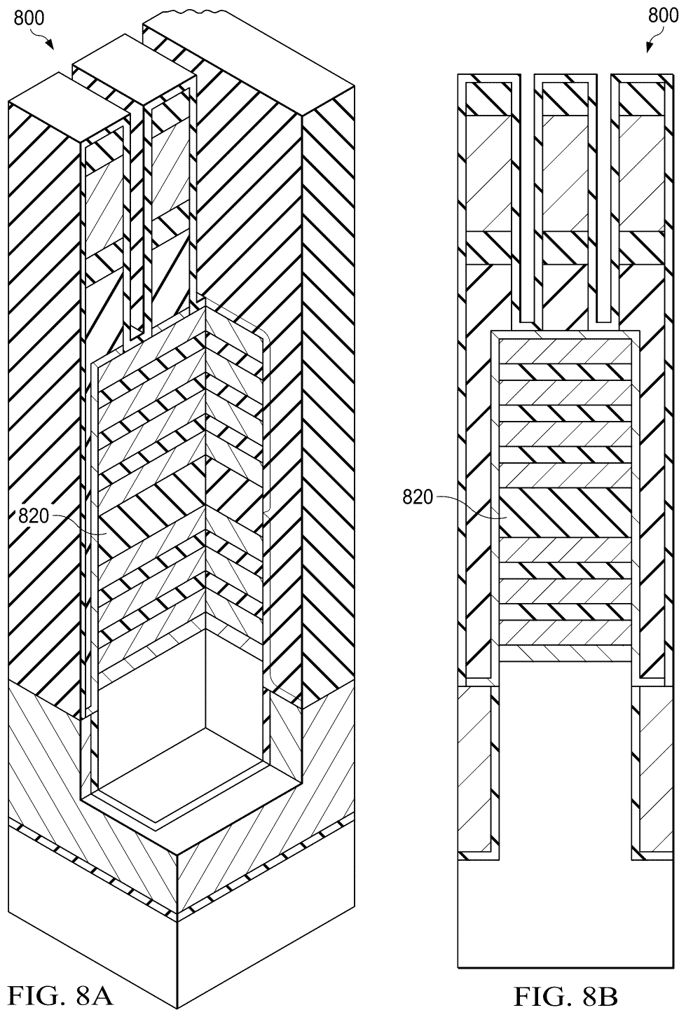

FIGS. 8A-8B show two views of a partially completed component 800. The partially completed component 800 includes structure formed by stressed atomic layer deposition (ALD) middle dielectric isolation (MDI) deposition. Embedded stressor 820 imparts an embedded stressor originated stress in at least one of the bottom nanosheet device and the top nanosheet device that imparts an embedded stressor originated force against at least one of the bottom nanosheet device and the top nanosheet device. This force can in-turn impart an embedded stressor originated device performance boost to at least one of the bottom nanosheet device and the top nanosheet device.

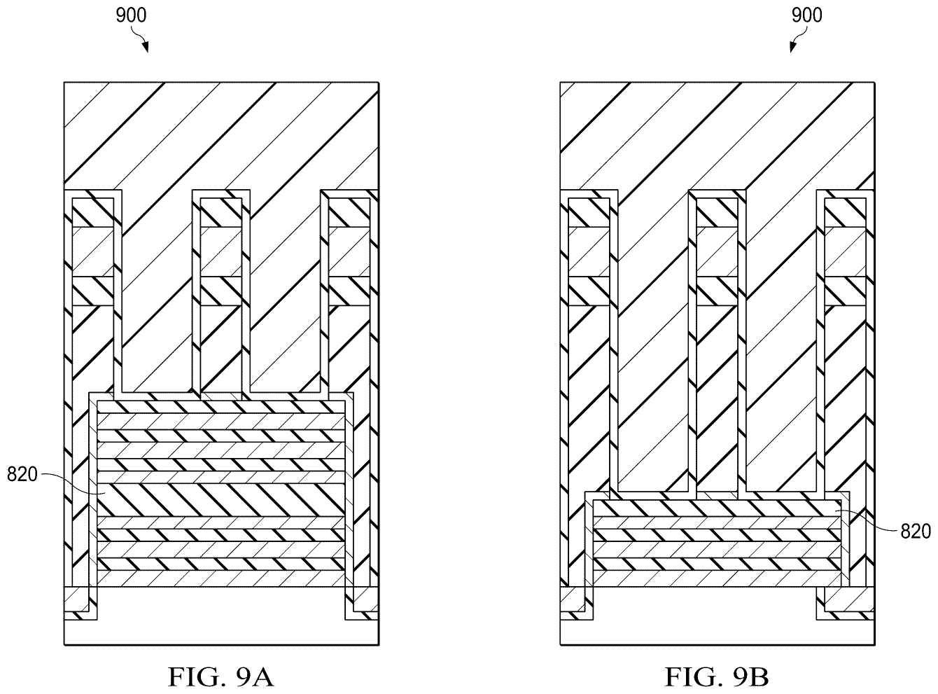

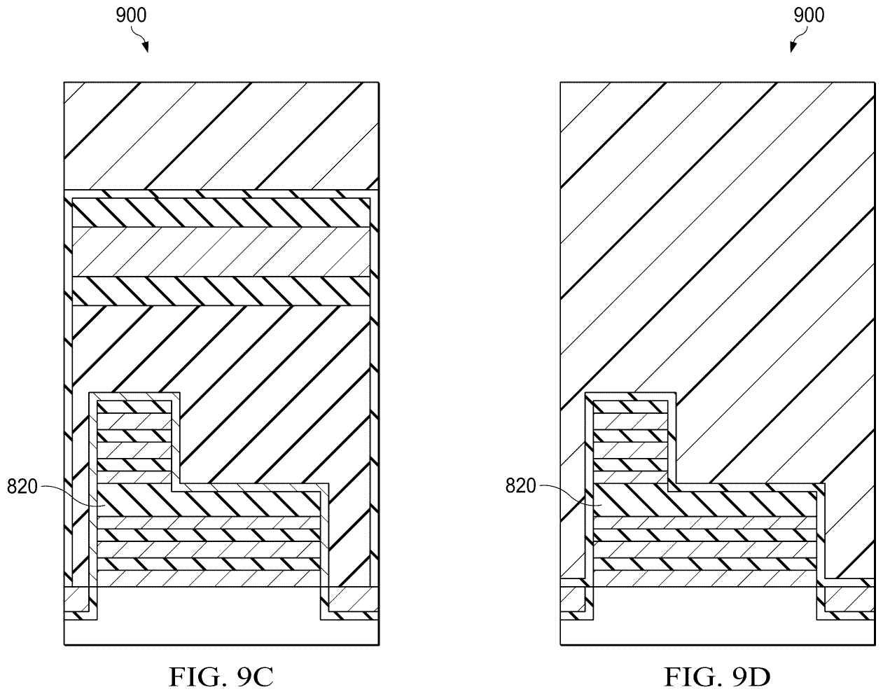

FIGS. 9A-9D show four views of a partially completed component 900. The partially completed component 900 includes a post stressed MDI formation.

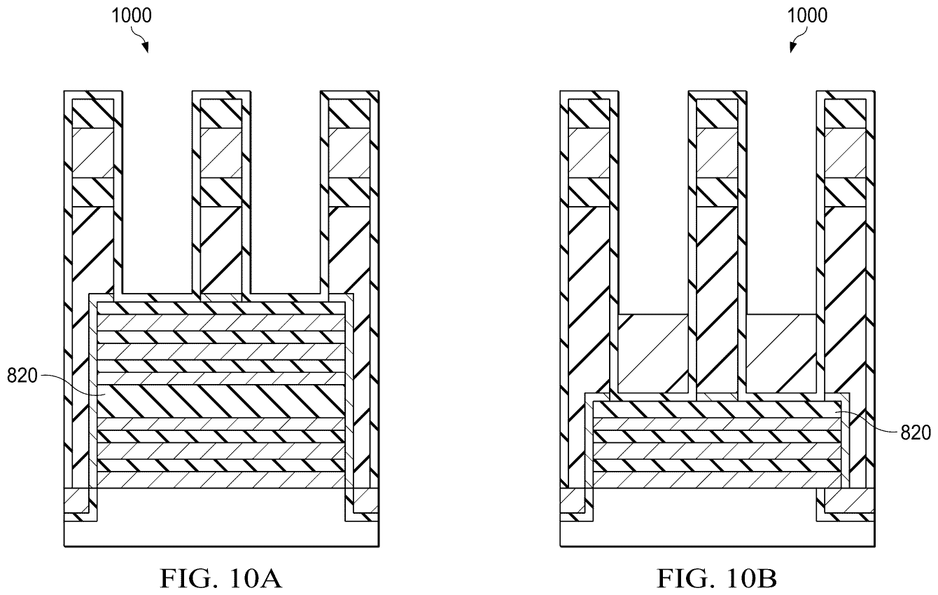

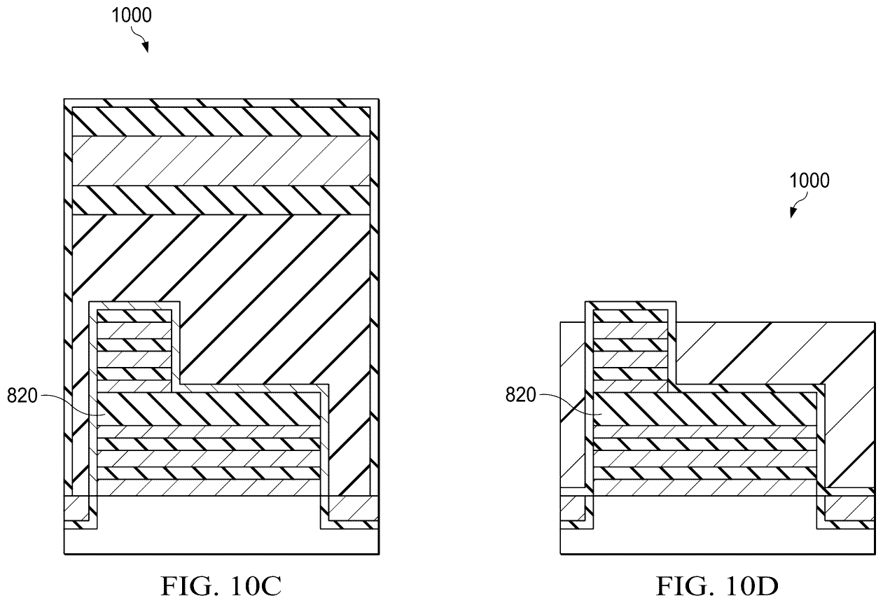

FIGS. 10A-10D show four views of a partially completed component 1000. The partially completed component 1000 includes structure formed by a spin on glass coating, CMP and controlled recess.

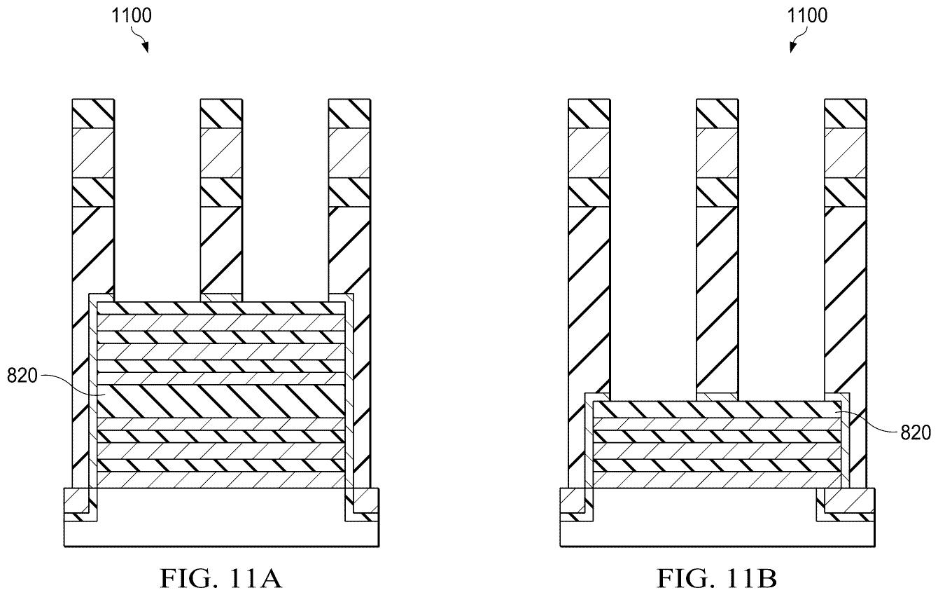

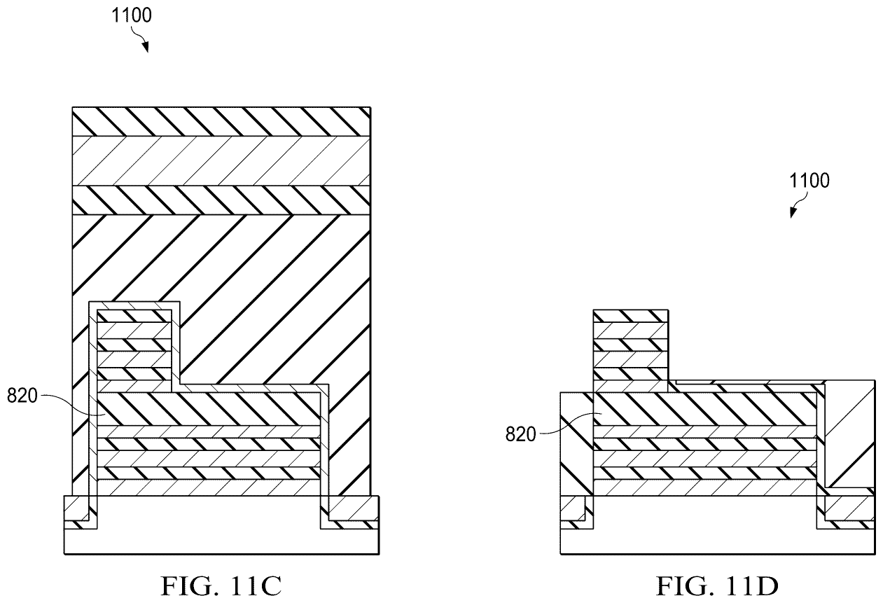

FIGS. 11A-11D show four views of a partially completed component 1100. The partially completed component 1100 includes structure formed by strip MDI dielectric from PC sidewalls.

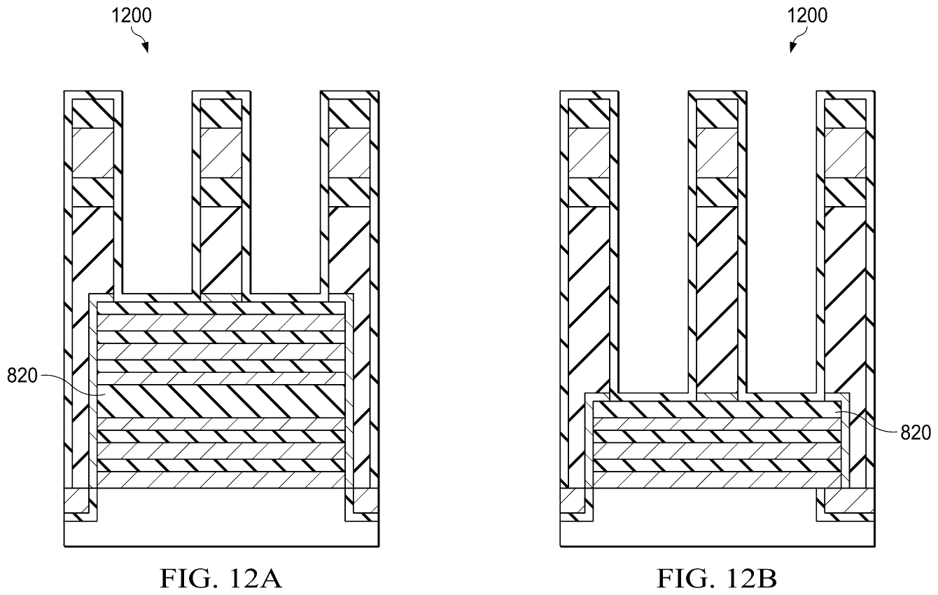

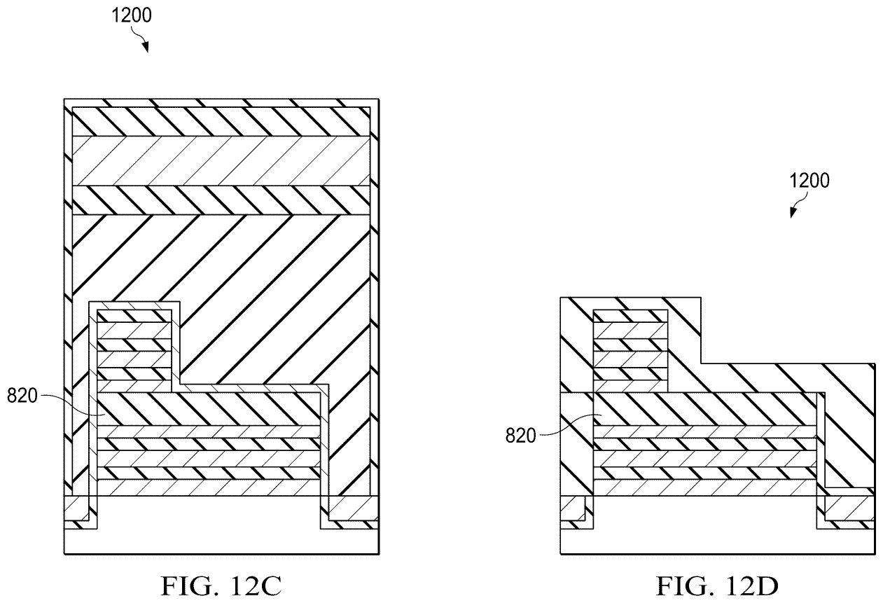

FIGS. 12A-12D show four views of a partially completed component 1200. The partially completed component 1200 includes structure formed by low-k spacer deposition and spacer RIE. Embodiments can include depositing a low-k spacer material on at least sidewalls of a top nanosheet component; and reactive ion etching the low-k spacer material.

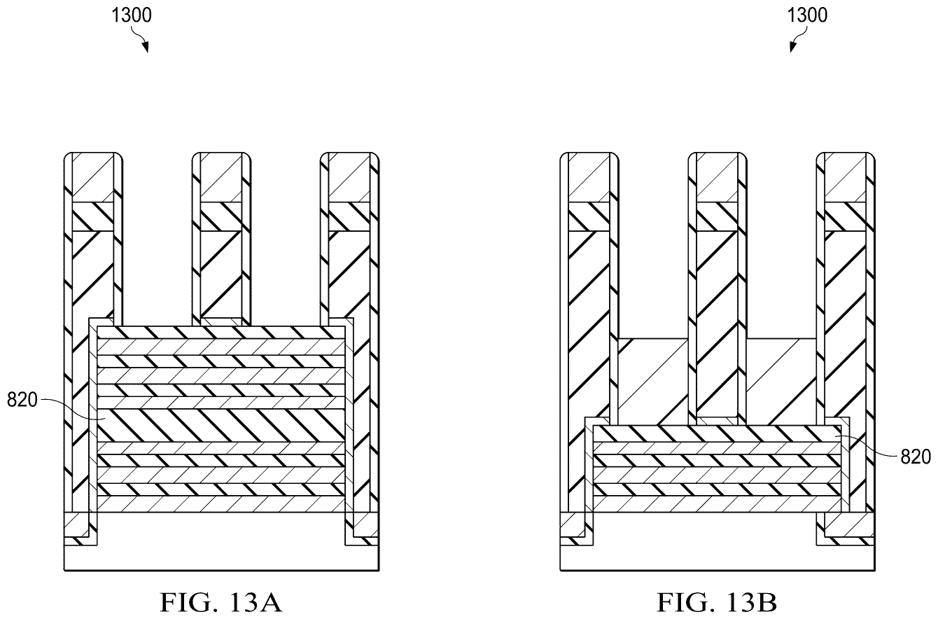

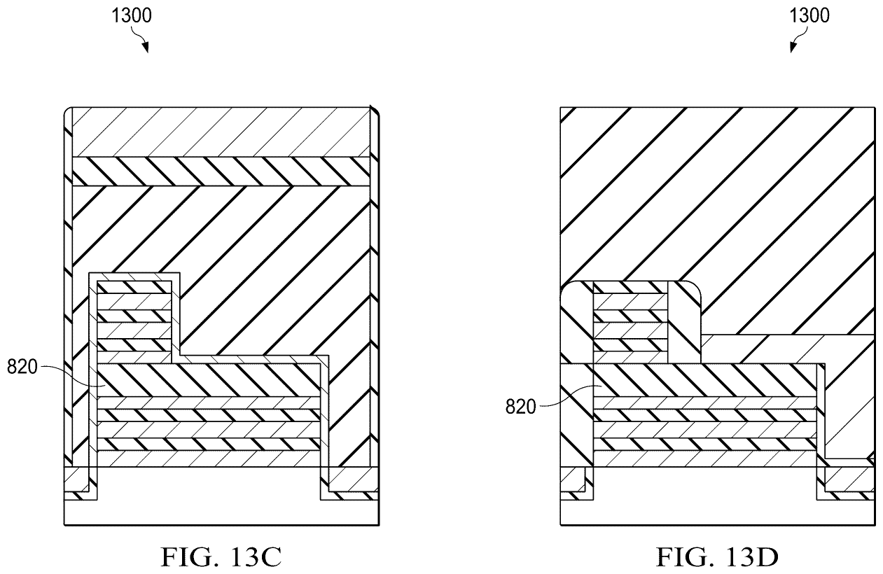

FIGS. 13A-13D show four views of a partially completed component 1300. The partially completed component 1300 includes structure formed by another spin on glass coating, CMP and recess.

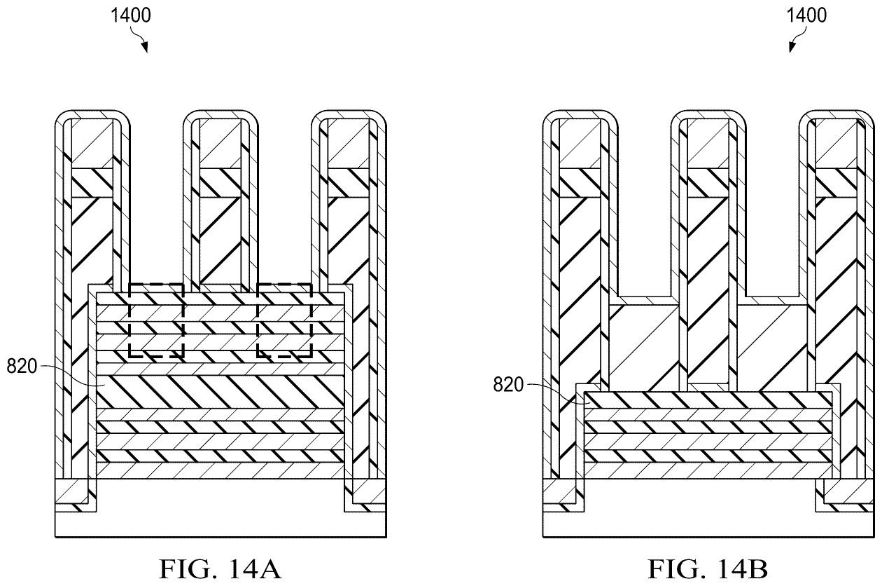

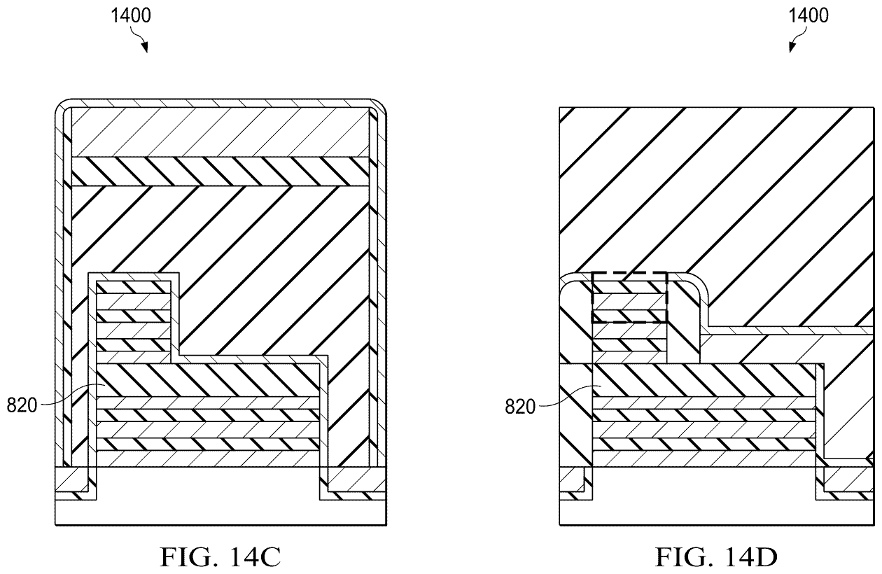

FIGS. 14A-14D show four views of a partially completed component 1400. The partially completed component 1400 includes structure formed by oxide spacer deposition and RIE. Thus, embodiments can include depositing oxide spacers and reactive ion etching.

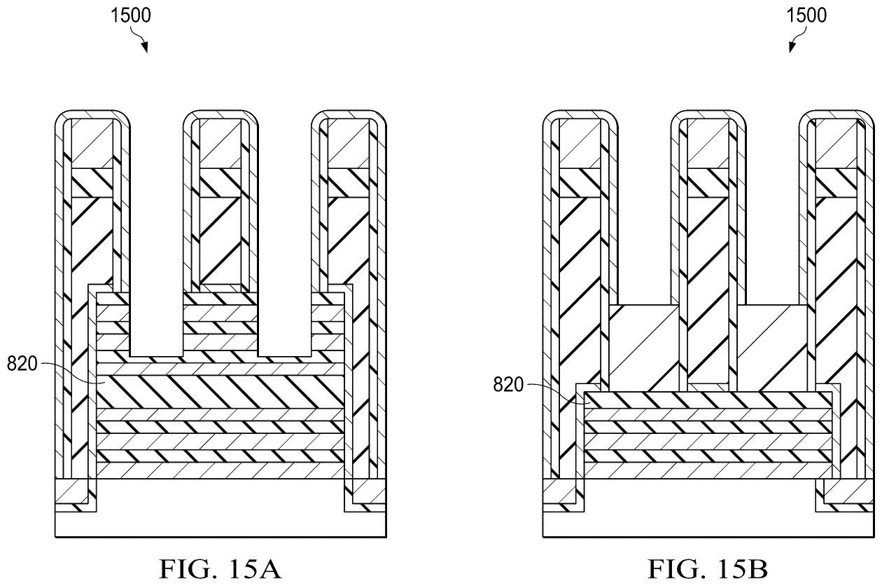

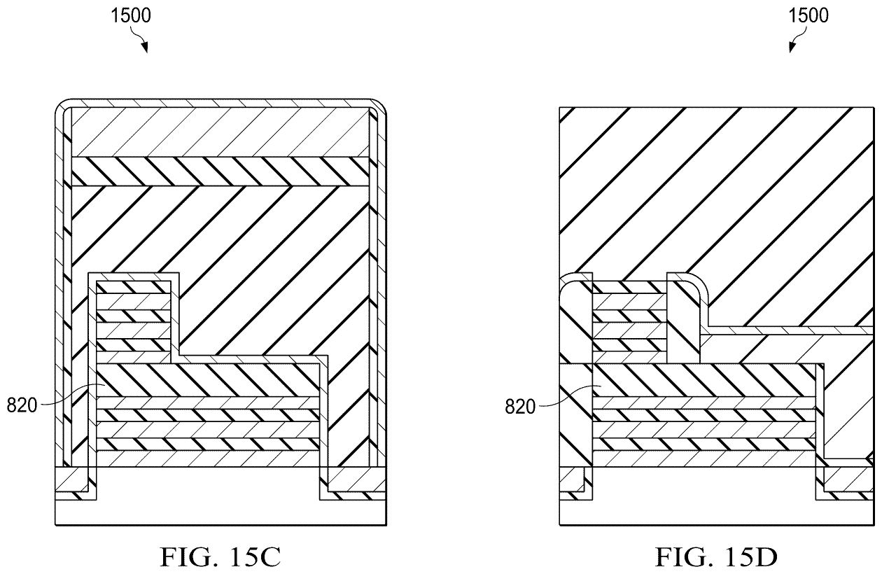

FIGS. 15A-15D show four views of a partially completed component 1500. The partially completed component 1500 includes structure formed by top device recess for inner spacer expose.

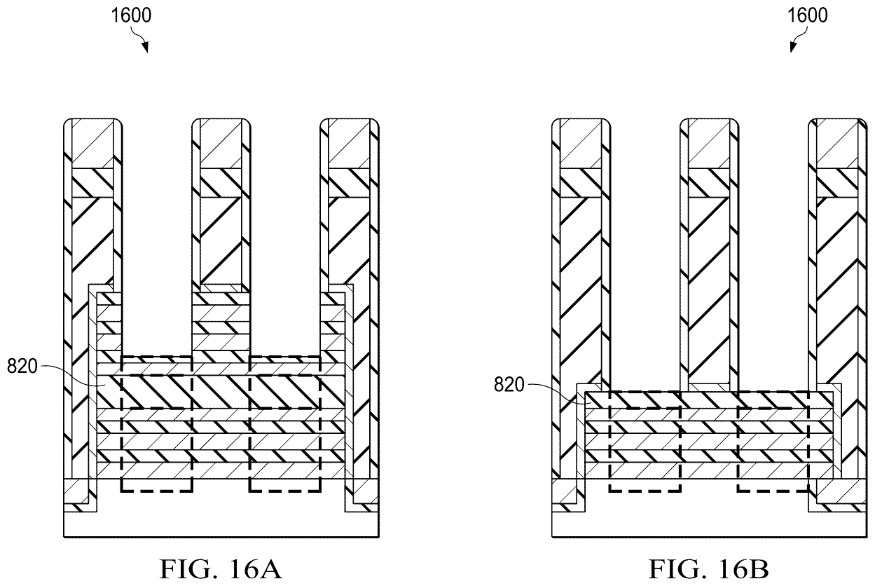

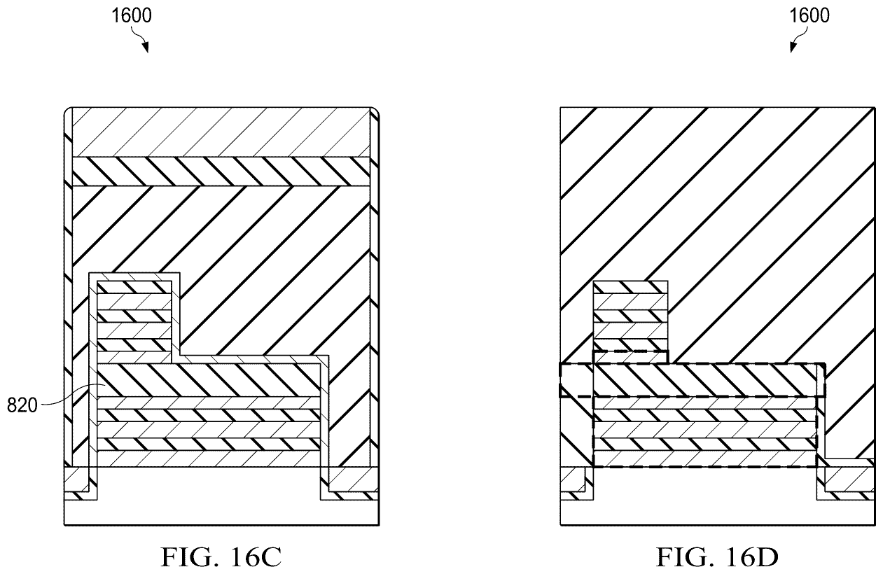

FIGS. 16A-16D show four views of a partially completed component 1600. The partially completed component 1600 includes structure formed by oxide spacer removal and SOG strip.

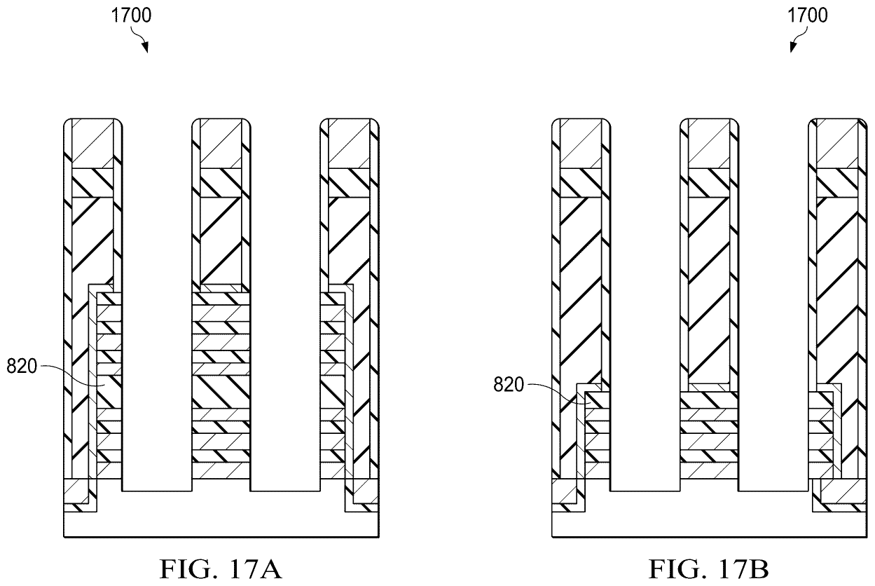

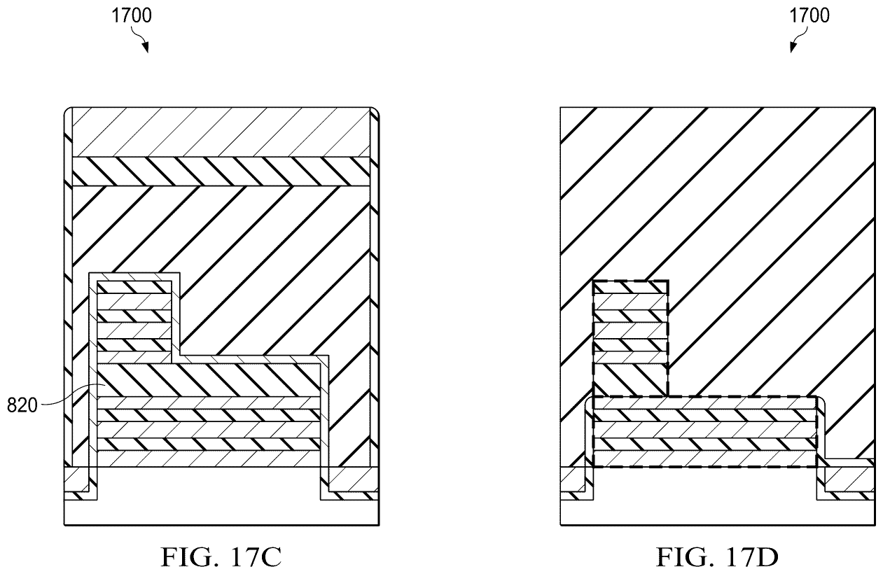

FIGS. 17A-17D show four views of a partially completed component 1700. The partially completed component 1700 includes structure formed by final layer of TNS and MDI removal.

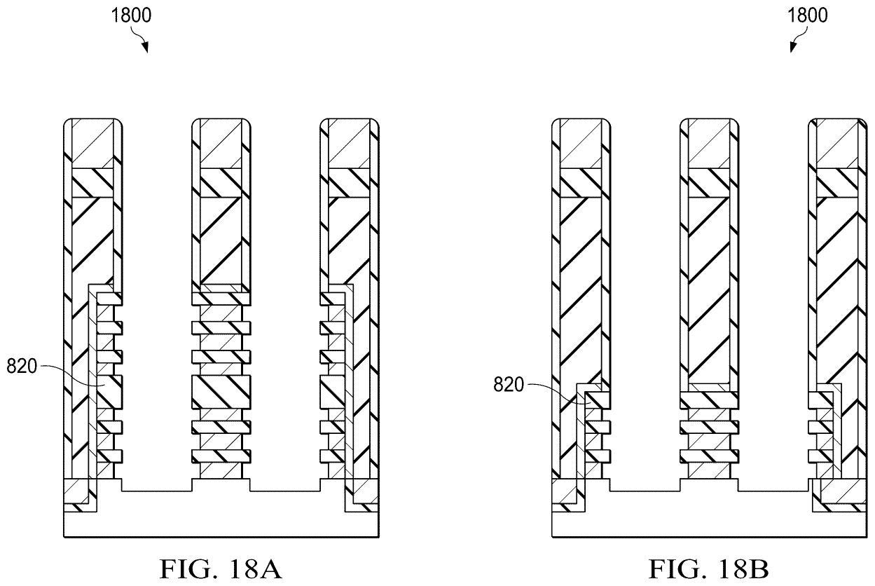

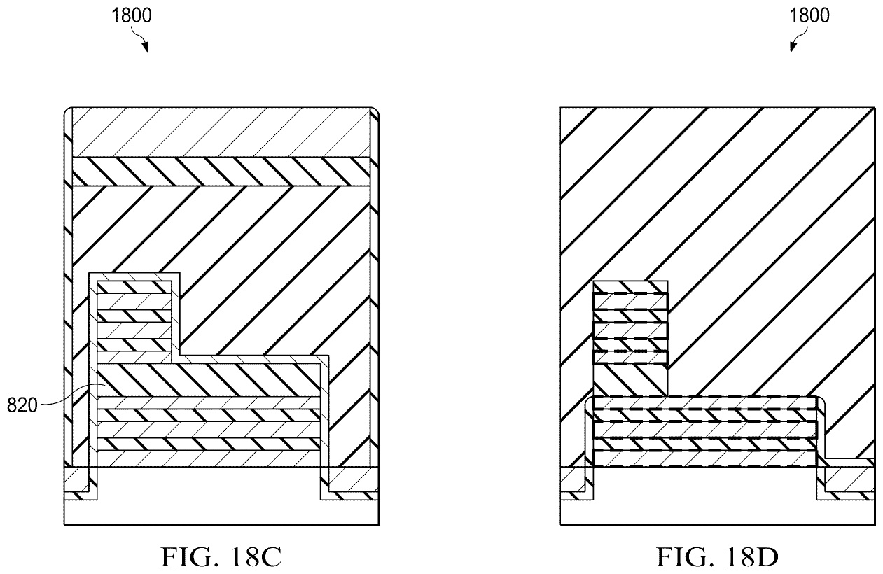

FIGS. 18A-18D show four views of a partially completed component 1800. The partially completed component 1800 includes structure formed by bottom device BNS recess.

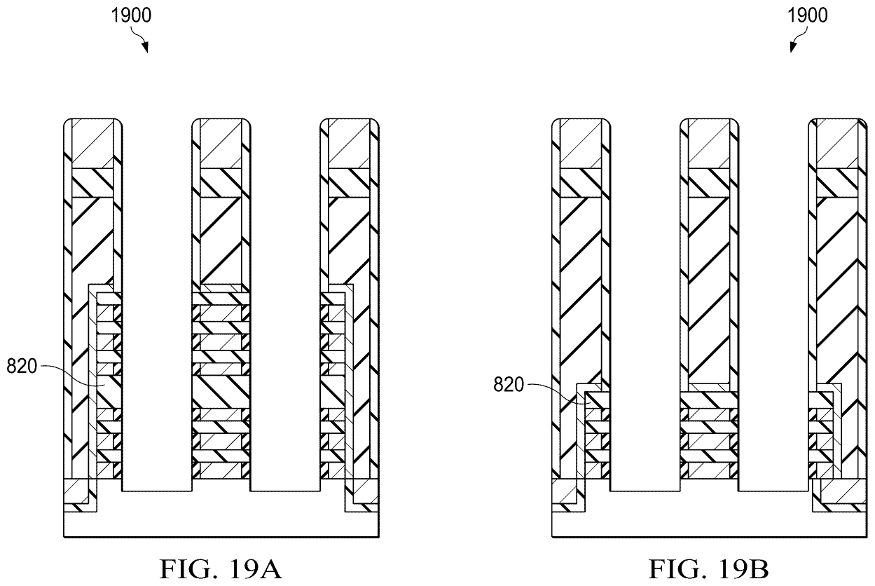

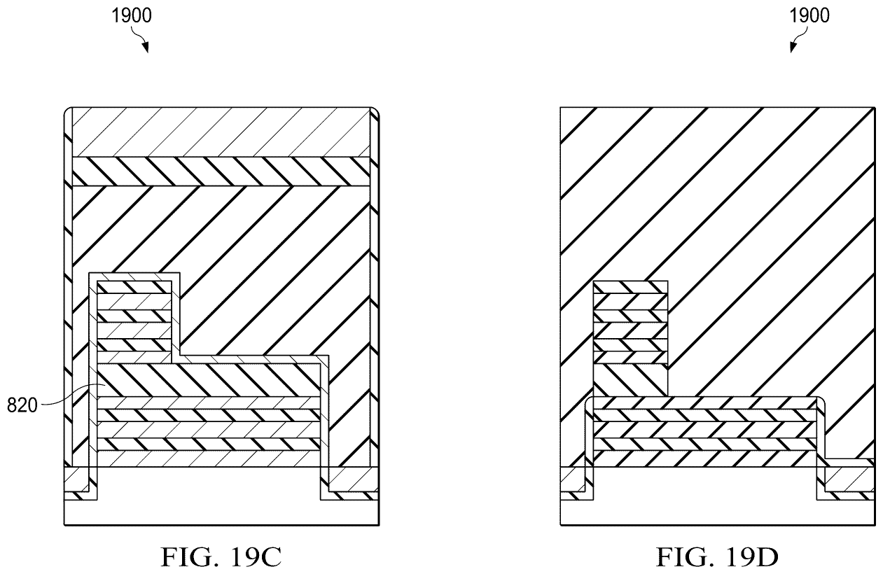

FIGS. 19A-19D show four views of a partially completed component 1900. The partially completed component 1900 includes structure formed by inner space indentation. Subsequent optional process flows can include a flow for epi module, a flow for POC module, a flow for NS release & RMG, and a flow for MOL and BEOL.

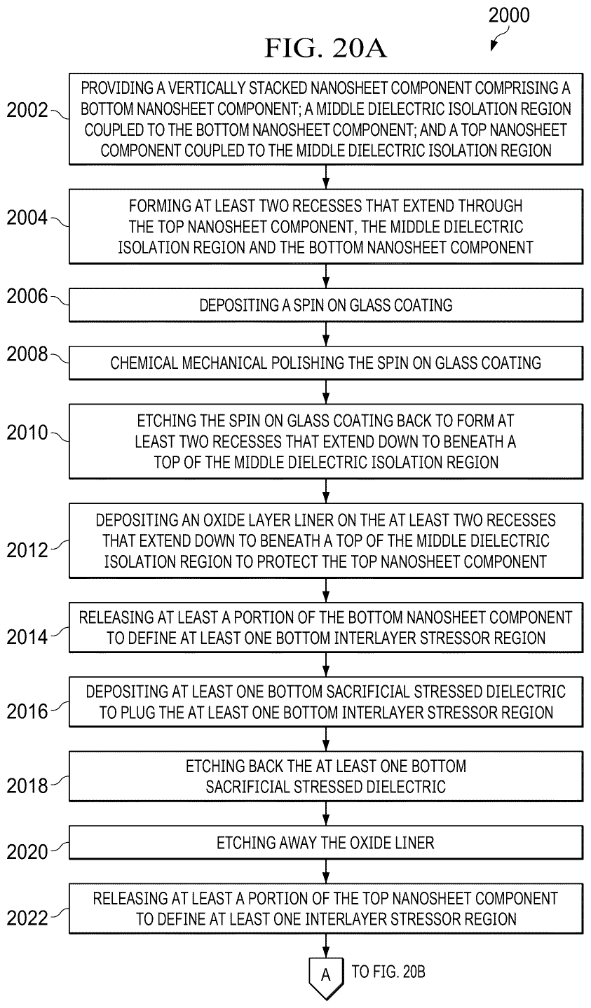

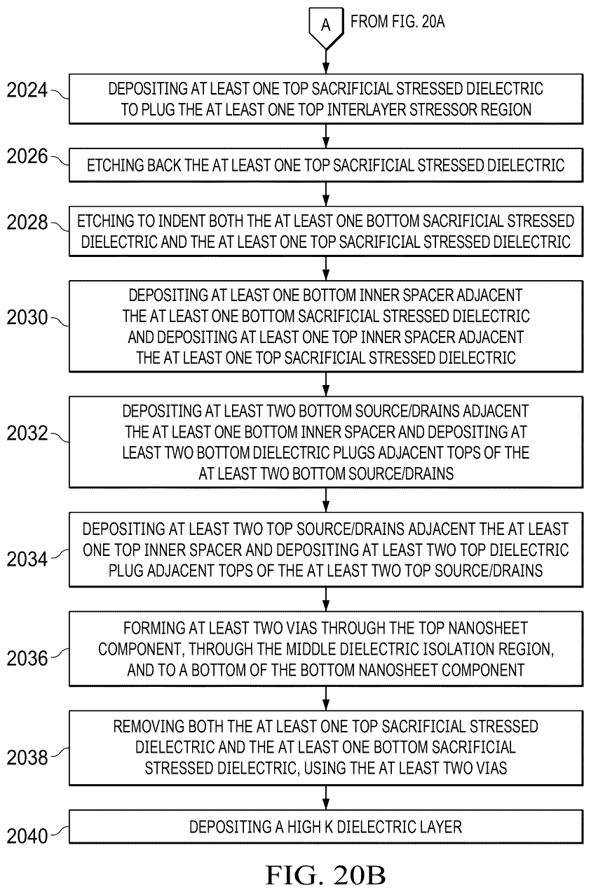

FIGS. 20A and 20B show a second flowchart 2000 illustrating steps for forming another embodiment of a vertically stacked 3D nanosheet field effect transistor component. Step 2002 includes providing a vertically stacked nanosheet component comprising a bottom nanosheet component; a middle dielectric isolation region coupled to the bottom nanosheet component; and a top nanosheet component coupled to the middle dielectric isolation region. Step 2004 includes forming at least two recesses that extend through the top nanosheet component, the middle dielectric isolation region and the bottom nanosheet component. Step 2006 includes depositing a spin on glass coating. Step 2008 includes chemical mechanical polishing the spin on glass coating. Step 2010 includes etching the spin on glass coating back to form at least two recesses that extend down to beneath a top of the middle dielectric isolation region. Step 2012 includes depositing an oxide liner on the at least two recesses that extend down to beneath a top of the middle dielectric isolation region to protect the top nanosheet component. Step 2014 includes releasing at least a portion of the bottom nanosheet component to define at least one bottom interlayer stressor region. Step 2016 includes depositing at least one bottom sacrificial stressed dielectric to plug the at least one bottom interlayer stressor region. Step 2018 includes etching back the at least one bottom sacrificial stressed dielectric. Step 2020 includes etching away the oxide liner. Step 2022 includes releasing at least a portion of the top nanosheet component to define at least one top interlayer stressor region. Step 2024 includes depositing at least one top sacrificial stressed dielectric to plug the at least one top interlayer stressor region. Step 2026 includes etching back the at least one top sacrificial stressed dielectric. Step 2028 includes etching to indent both the at least one bottom sacrificial stressed dielectric and the at least one top sacrificial stressed dielectric. Step 2030 includes depositing at least one bottom inner spacer adjacent the at least one bottom sacrificial stressed dielectric and depositing at least one top inner spacer adjacent the at least one top sacrificial stressed dielectric. Step 2032 includes depositing at least two bottom source/drains adjacent the at least one bottom inner spacer and depositing at least two bottom dielectric plugs adjacent tops of the at least two bottom source/drains. Step 2034 includes depositing at least two top source/drains adjacent the at least one top inner spacer and depositing at least two top dielectric plug adjacent tops of the at least two top source/drains. Step 2036 includes forming at least two vias through the top nanosheet component, through the middle dielectric isolation region, and to a bottom of the bottom nanosheet component. Step 2038 includes removing both the at least one top sacrificial stressed dielectric and the at least one bottom sacrificial stressed dielectric, using the at least two vias. Step 2040 includes depositing a high K dielectric layer.

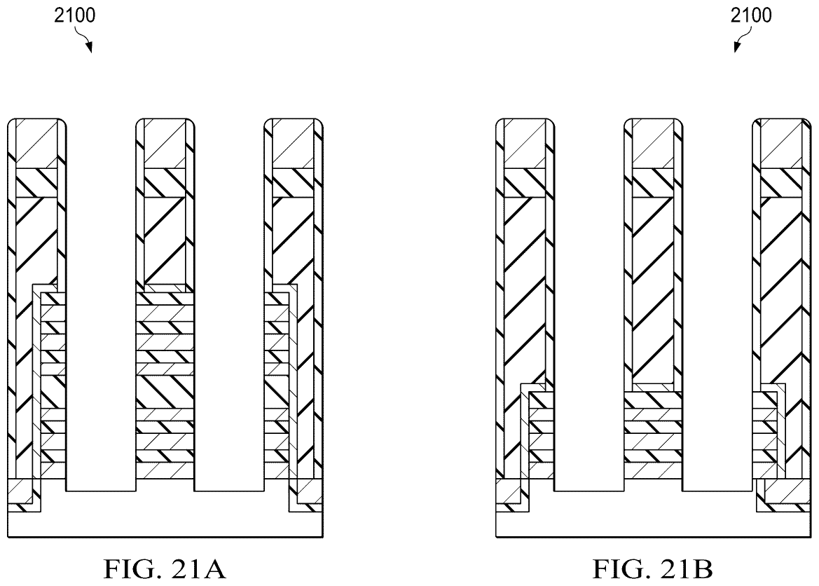

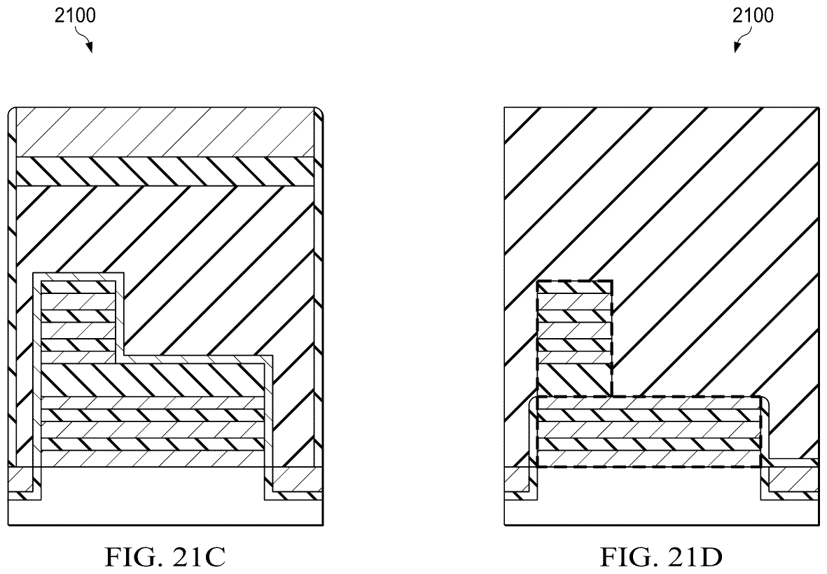

FIGS. 21A-21D show four views of a partially completed component 2100. The partially completed component 2100 includes structure formed by post stacked FET device recess.

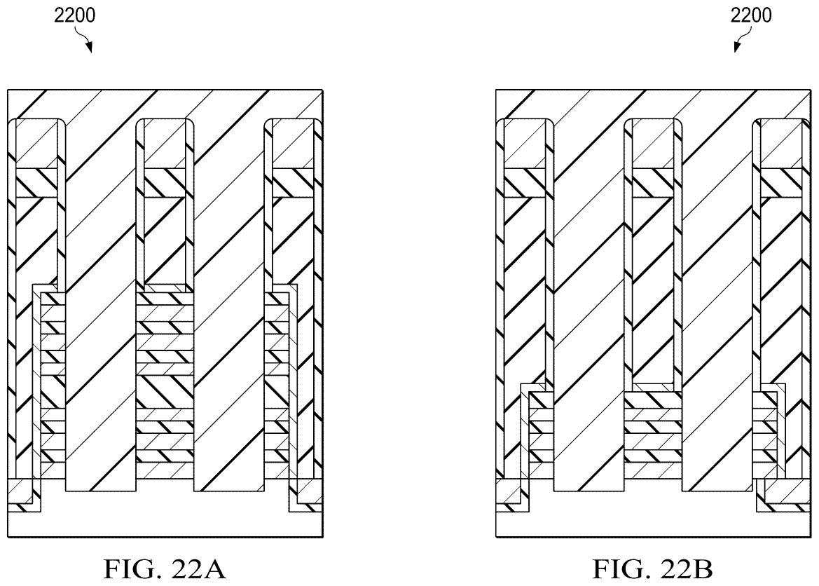

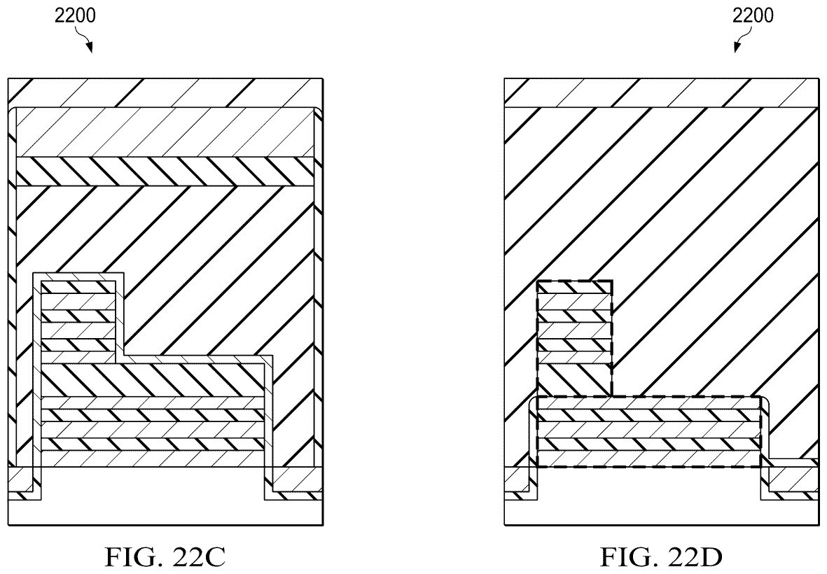

FIGS. 22A-22D show four views of a partially completed component 2200. The partially completed component 2200 includes structure formed by SOG coat, CMP for controlled recess.

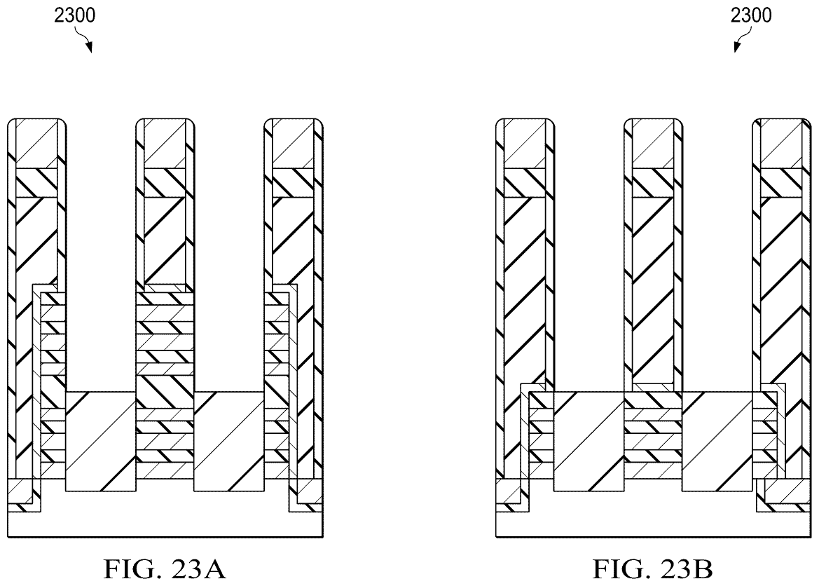

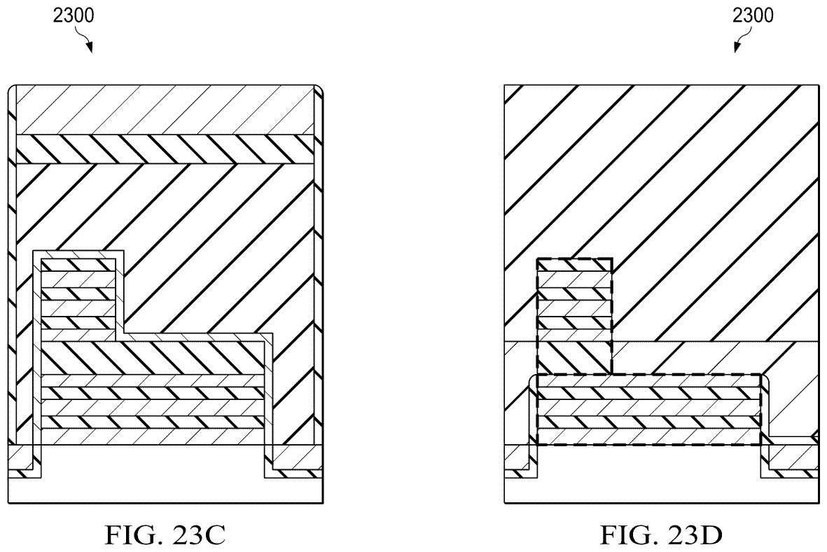

FIGS. 23A-23D show four views of a partially completed component 2300. The partially completed component 2300 includes structure formed by SOG etch back to middle of MDI.

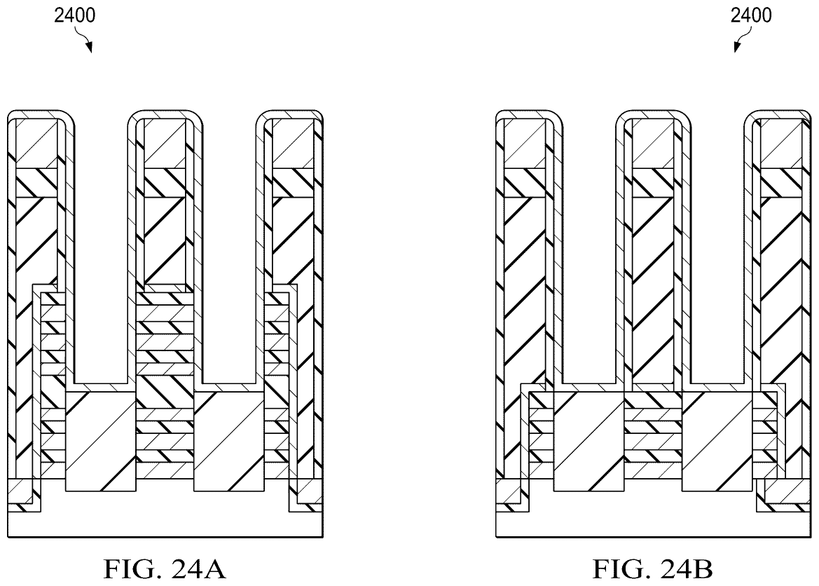

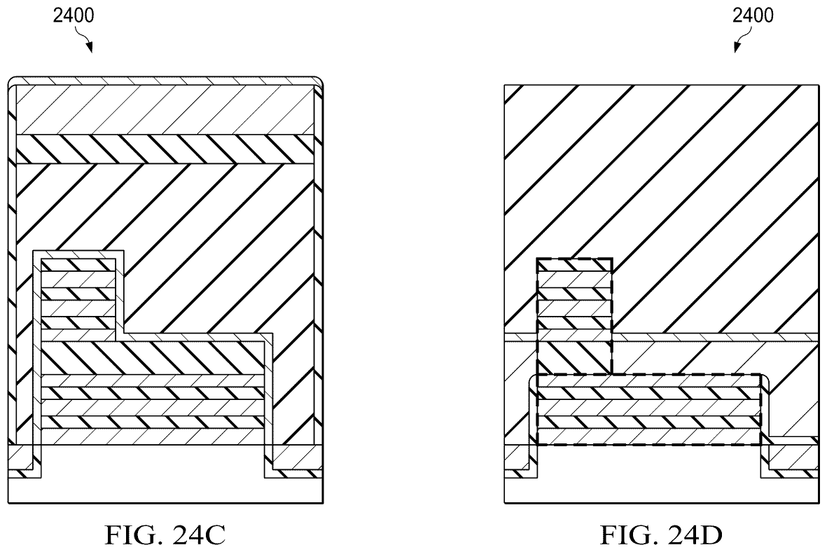

FIGS. 24A-24D show four views of a partially completed component 2400. The partially completed component 2400 includes structure formed by oxide liner for top NS protection.

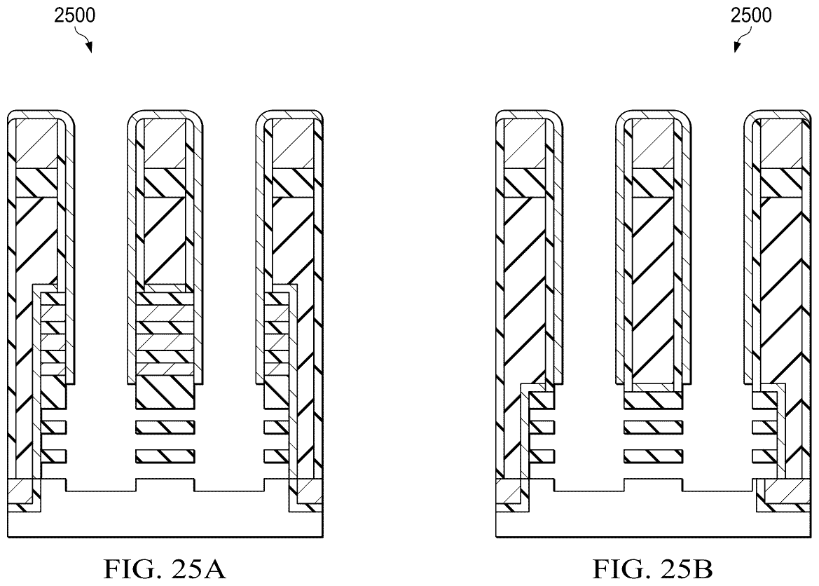

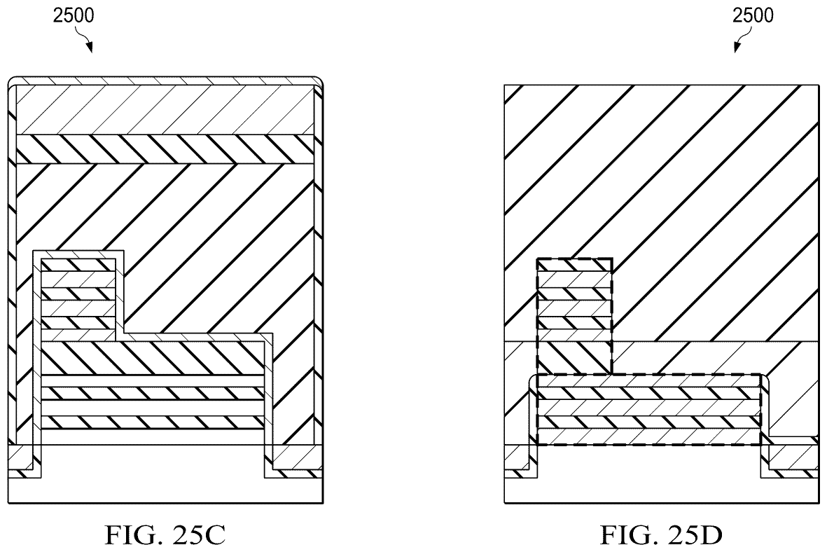

FIGS. 25A-25D show four views of a partially completed component 2500. The partially completed component 2500 includes structure formed by complete release of BNS suspended SiGe.

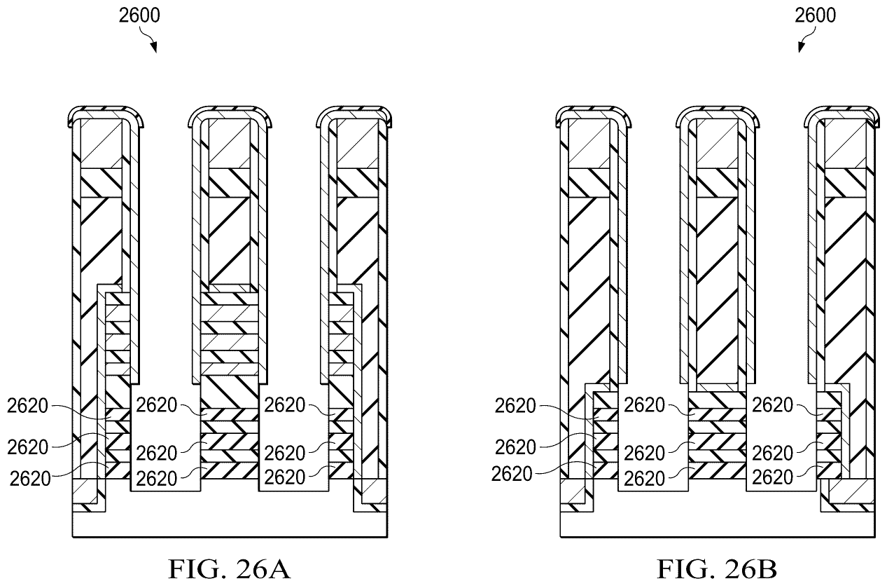

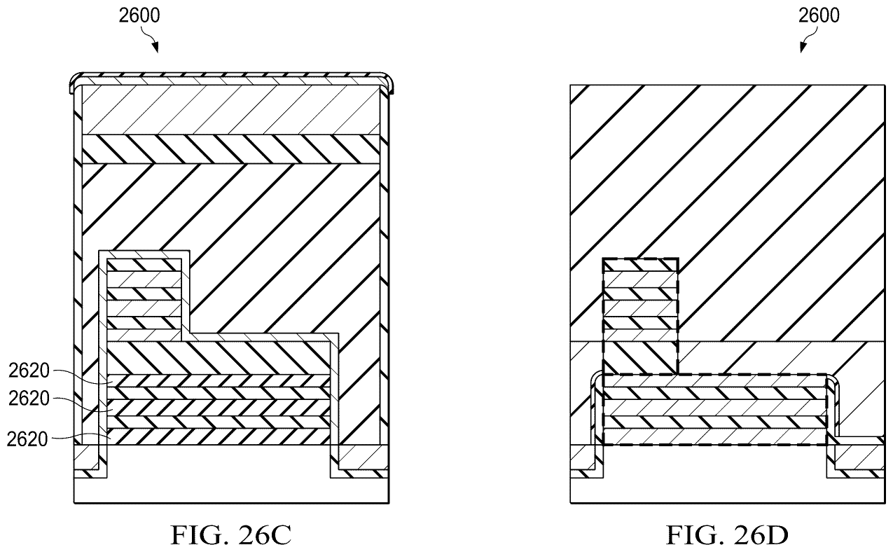

FIGS. 26A-26D show four views of a partially completed component 2600. The partially completed component 2600 includes bottom nanosheet device sacrificial stressed interlayers 2620 formed by a first sacrificial stressed dielectric plug and etch back. Bottom nanosheet device sacrificial stressed interlayers 2620 are located between the bottom nanosheet device nanosheets. Bottom nanosheet device sacrificial stressed interlayers 2620 can impart a bottom nanosheet device sacrificial stressed interlayers originated stress in the bottom nanosheet device that imparts a force against the bottom nanosheet device. This force can in-turn impart a bottom nanosheet device sacrificial stressed interlayers originated device performance boost to the bottom nanosheet device.

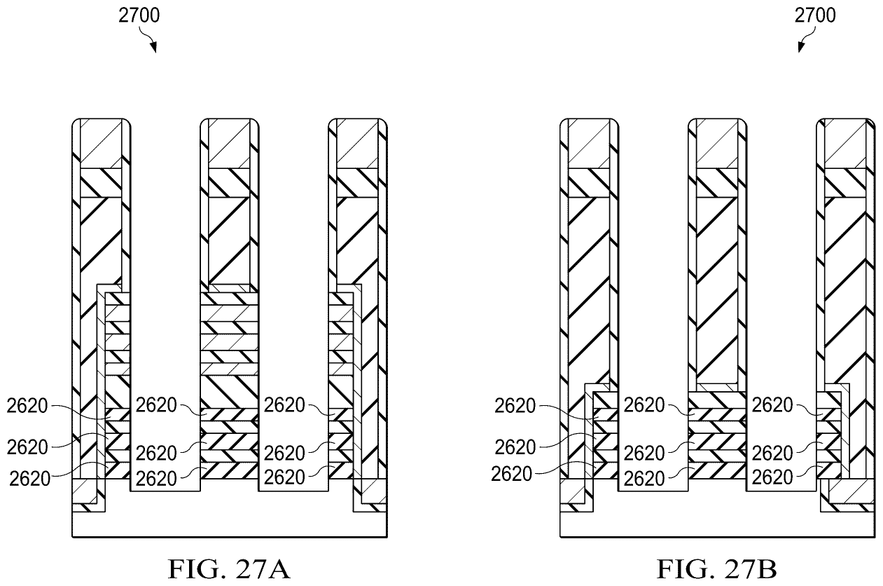

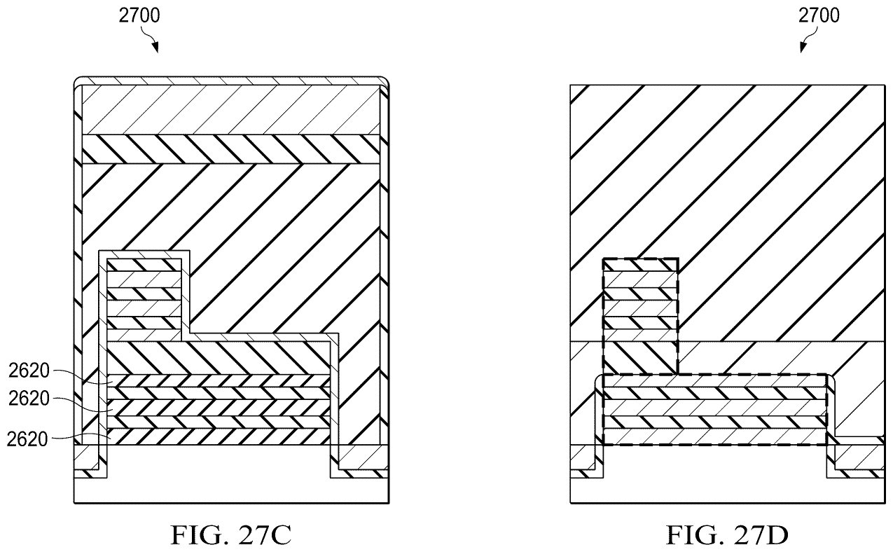

FIGS. 27A-27D show four views of a partially completed component 2700. The partially completed component 2700 includes structure formed by top device protective oxide liner etch.

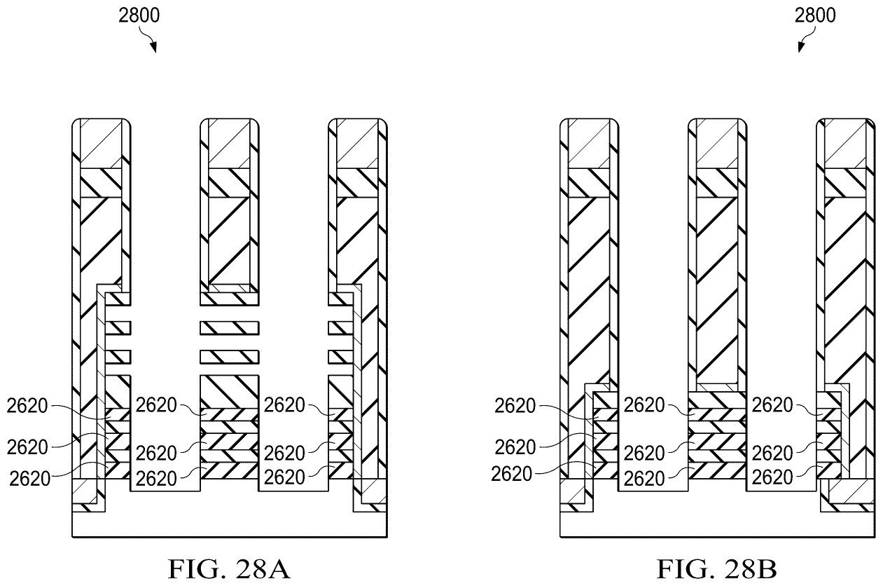

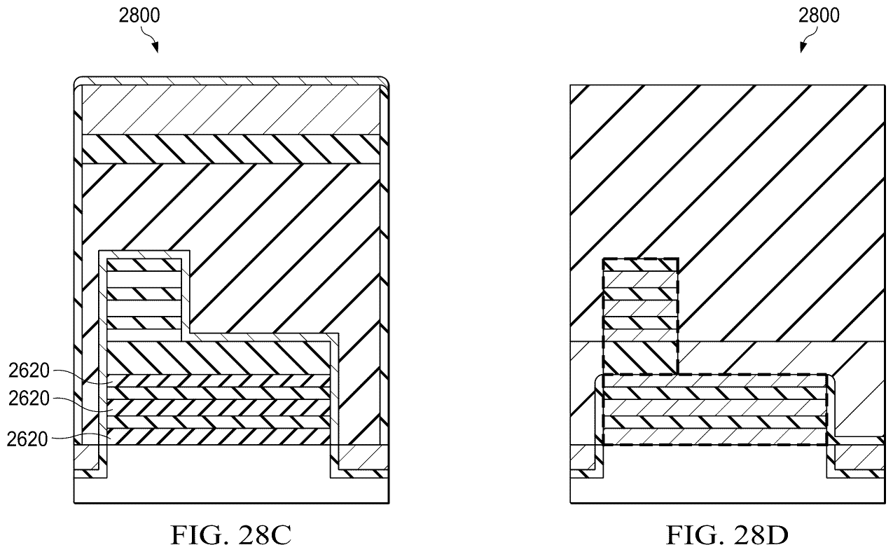

FIGS. 28A-28D show four views of a partially completed component 2800. The partially completed component 2800 includes structure formed by complete release of TNS suspended SiGe.

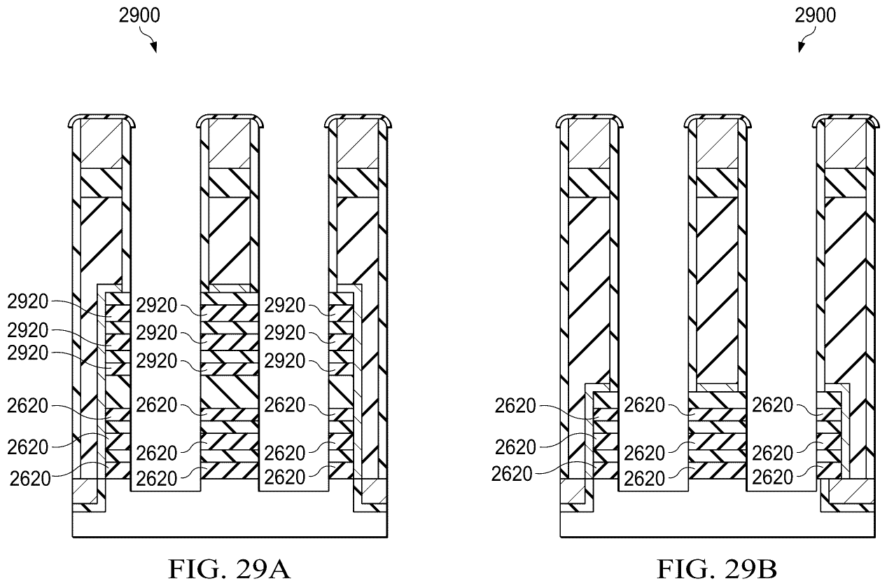

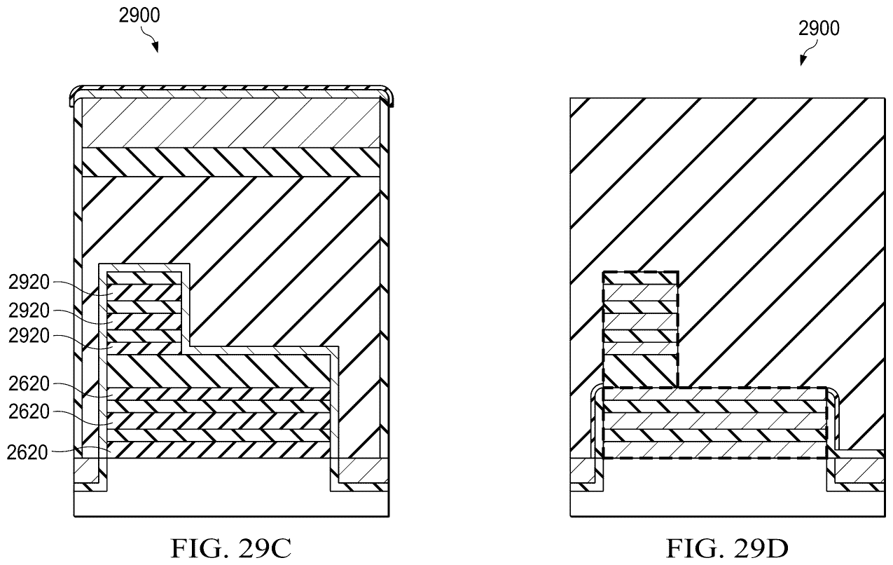

FIGS. 29A-29D show four views of a partially completed component 2900. The partially completed component 2900 includes top nanosheet device sacrificial stressed interlayers 2920 formed by a second sacrificial stressed dielectric plug and etch back. Top nanosheet device sacrificial stressed interlayers 2920 are located between the top nanosheet device nanosheets. Top nanosheet device sacrificial stressed interlayers 2920 can impart a top nanosheet device sacrificial stressed interlayers originated stress in the top nanosheet device that imparts a force against the top nanosheet device. This force can in-turn impart a top nanosheet device sacrificial stressed interlayers originated device performance boost to the top nanosheet device. In embodiments, the bottom nanosheet device can include a bottom plurality of silicon nanosheet channels and the top nanosheet device can include a top plurality of silicon nanosheet channels. An at least one interlayer originated stress can be imparted by at least one sacrificial interlayer stressor located in at least one of the bottom plurality of silicon nanosheet channels and the top plurality of silicon nanosheet channels. Embodiments can include depositing at least one bottom sacrificial stressed dielectric to plug the at least one bottom interlayer stressor region by plasma enhanced atomic layer deposition and depositing at least one top sacrificial stressed dielectric to plug the at least one top interlayer stressor region by plasma enhanced atomic layer deposition.

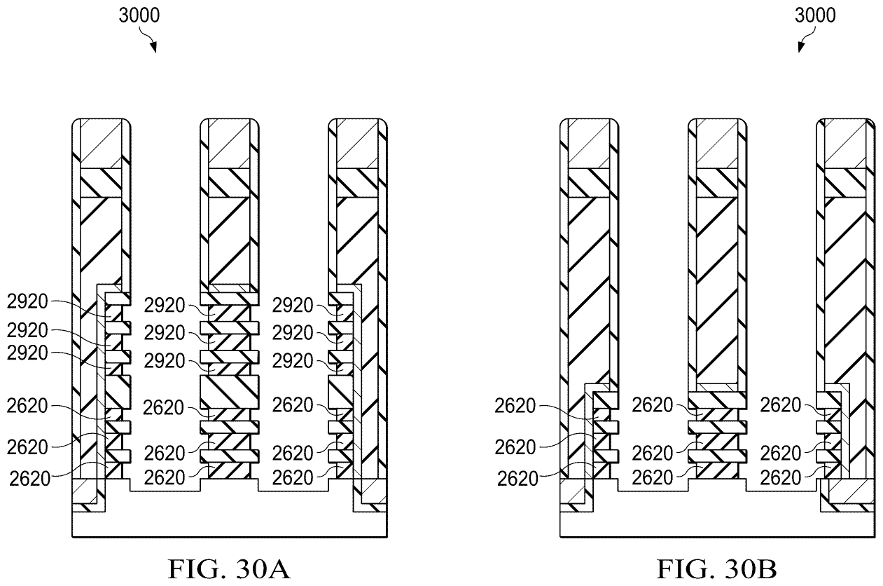

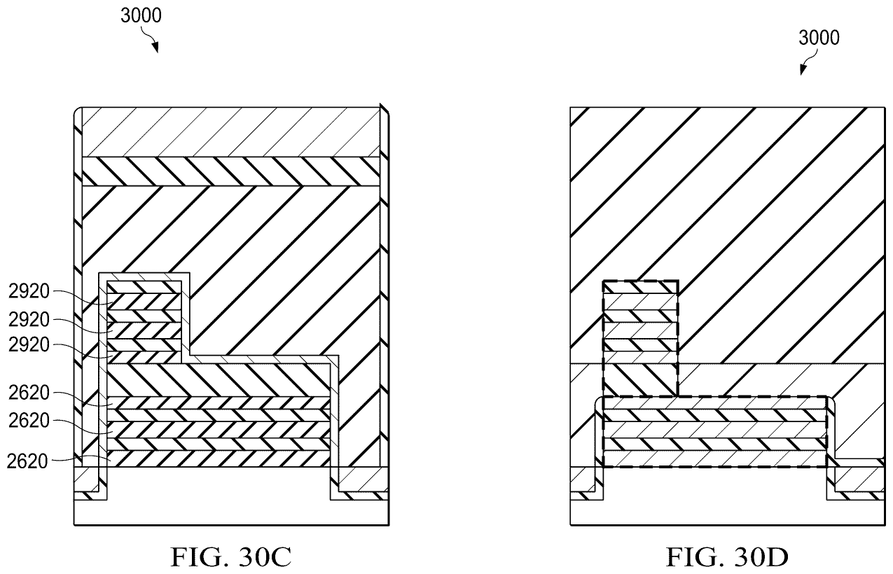

FIGS. 30A-30D show four views of a partially completed component 3000. The partially completed component 3000 includes structure formed by indentation of top/bottom sacrificial dielectrics.

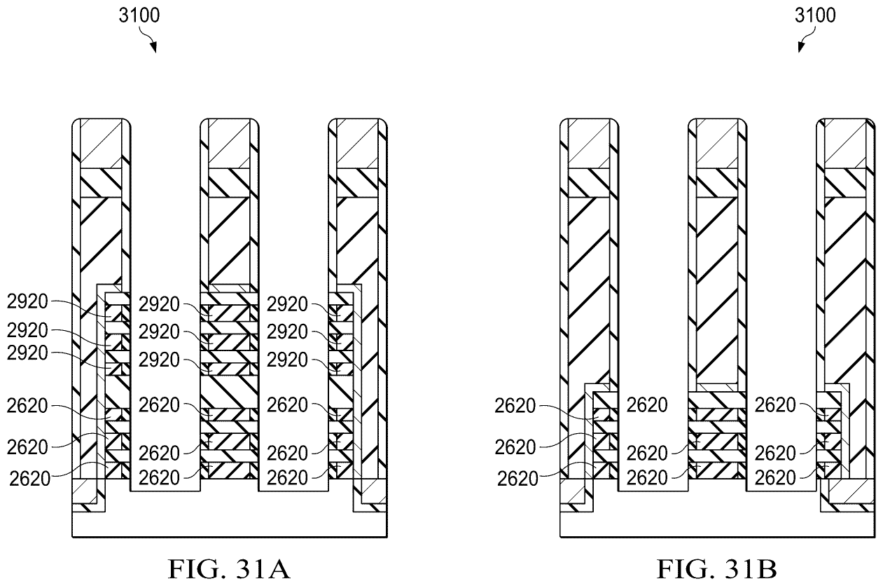

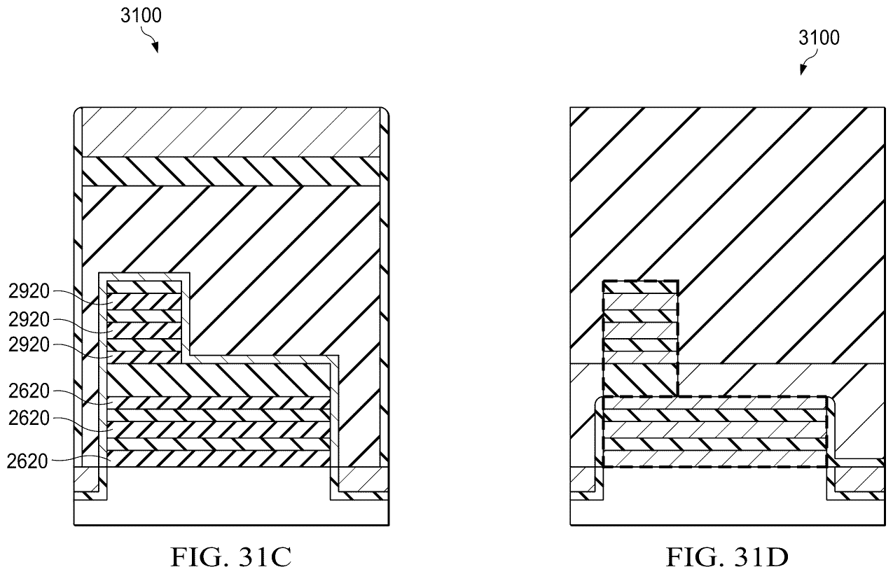

FIGS. 31A-31D show four views of a partially completed component 3100. The partially completed component 3100 includes structure formed by inner spacer deposition and etch.

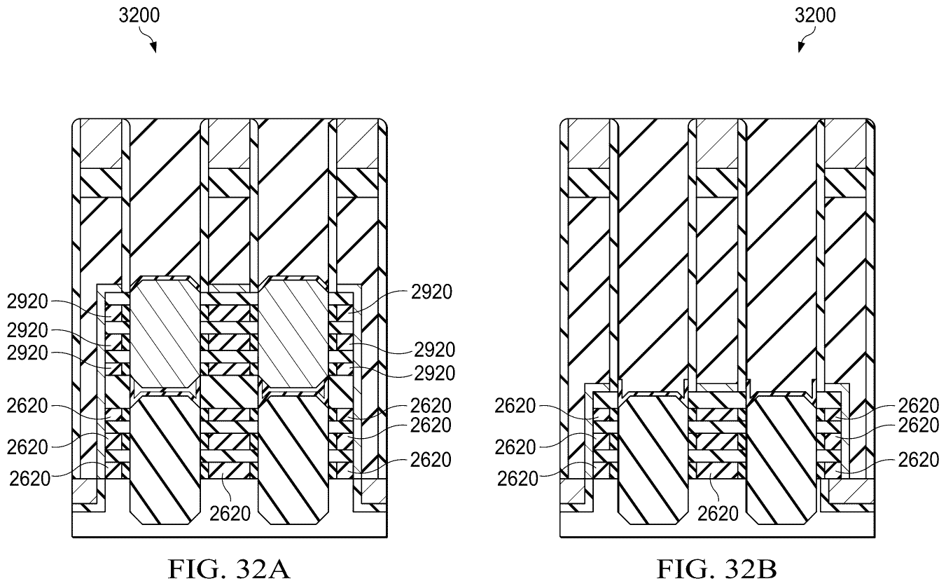

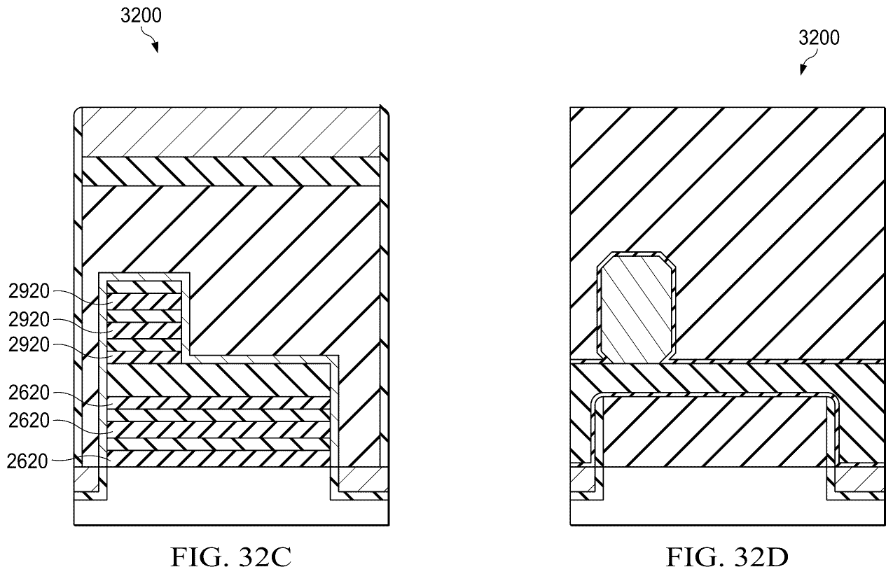

FIGS. 32A-32D show four views of a partially completed component 3200. The partially completed component 3200 includes structure formed by dual epi formation with dielectric plug.

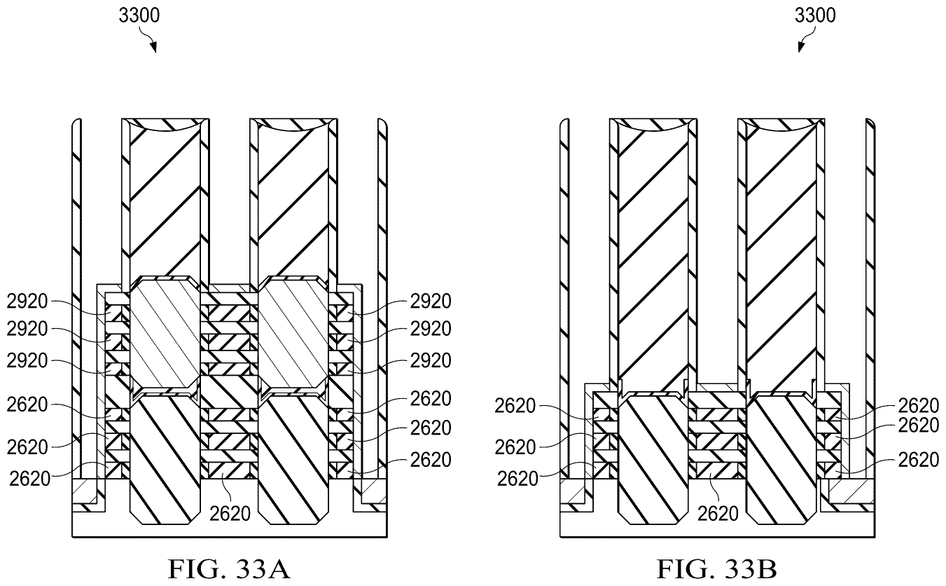

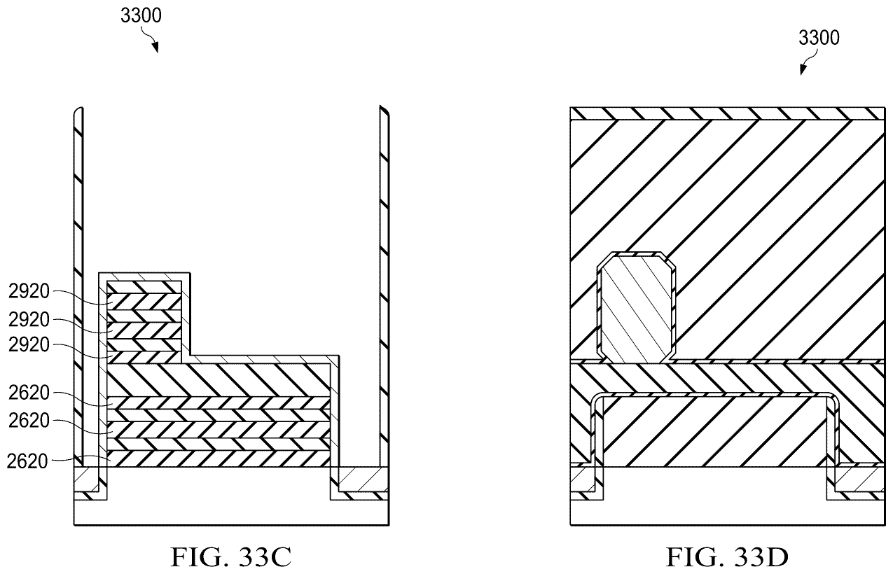

FIGS. 33A-33D show four views of a partially completed component 3300. The partially completed component 3300 includes structure formed by ILD deposition and POC HM stack removal and dummy poly pull RMG module.

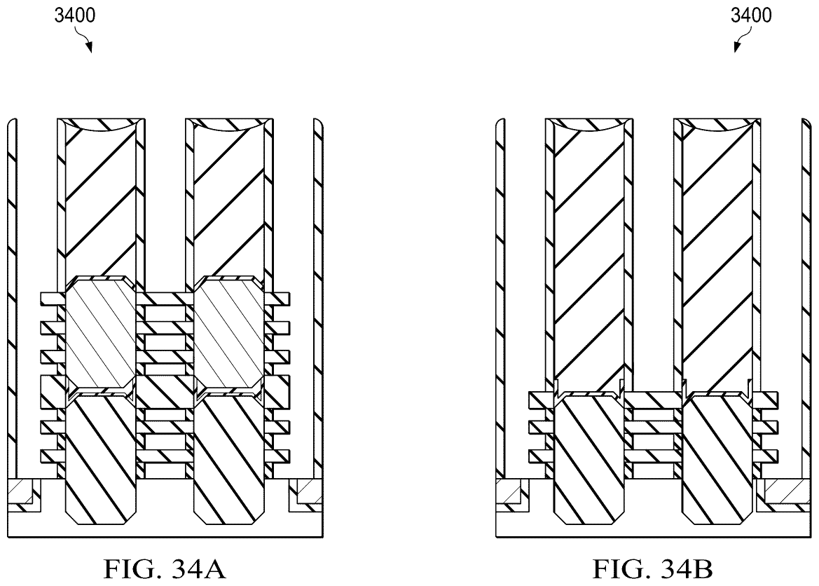

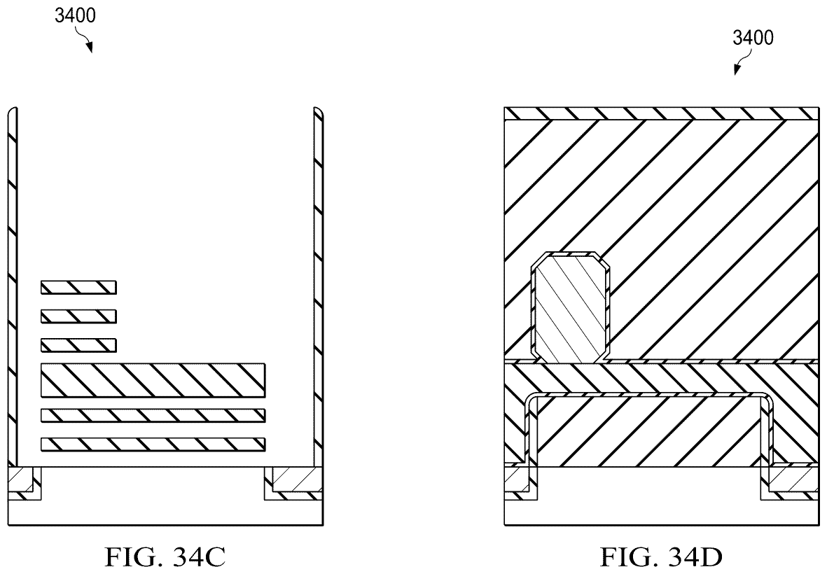

FIGS. 34A-34D show four views of a partially completed component 3400. The partially completed component 3400 includes structure formed by sacrificial nanosheet interlayer dielectric removal and nanosheet release.

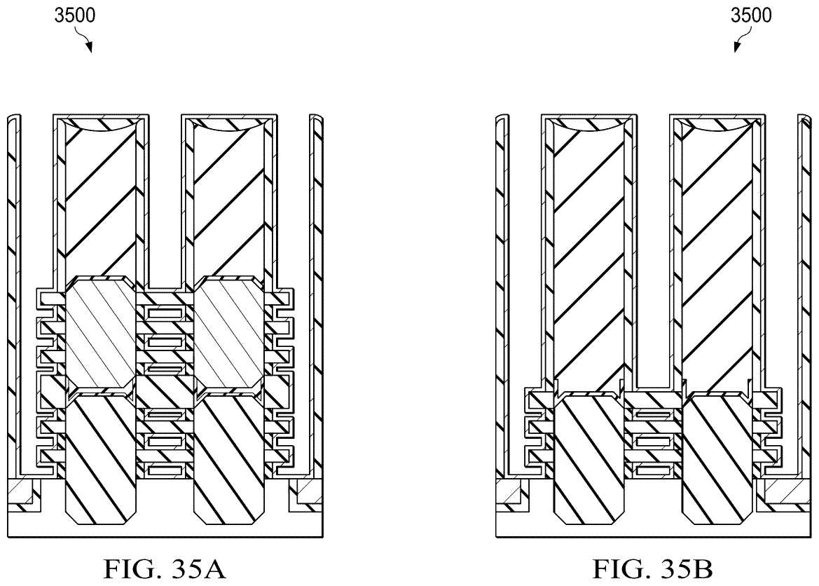

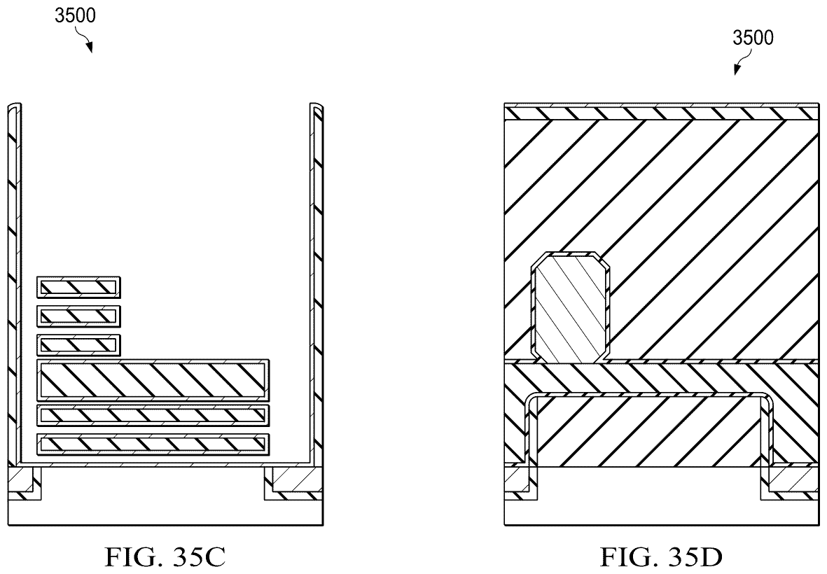

FIGS. 35A-35D show four views of a partially completed component 3500. The partially completed component 3500 includes structure formed by IL plus high K deposition.

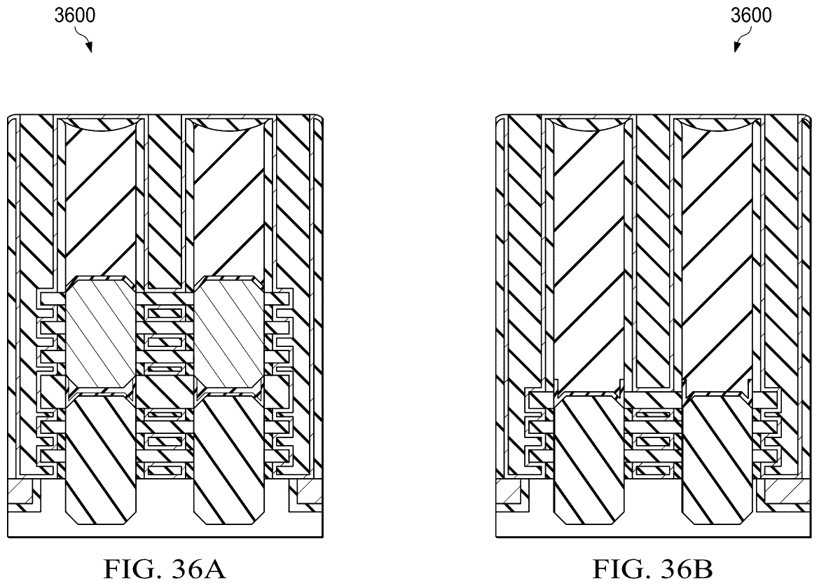

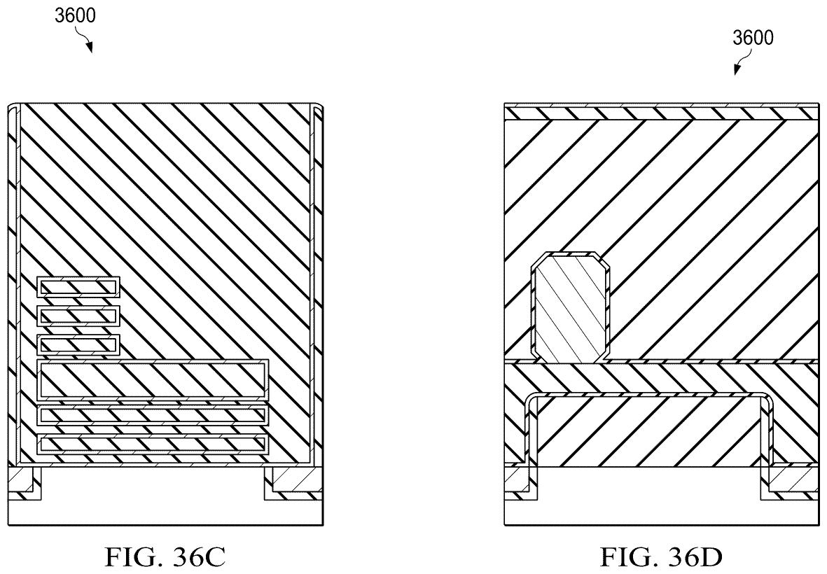

FIGS. 36A-36D show four views of a partially completed component 3600. The partially completed component 3600 includes structure formed by work function metal and gate metallization. Subsequent optional process flows can include a flow for MOL and a flow for BEOL.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding of the various embodiments. But the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C,” may include item A, item A and item B, or item B. This example also may include item A, item B, and item C, or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A vertically stacked 3D nanosheet field effect transistor component, comprising:
a bottom nanosheet device comprising a first bottom source/drain and a second bottom source/drain;
a middle dielectric isolation region coupled to the bottom nanosheet device; and
a top nanosheet device coupled to the middle dielectric isolation region, the top nanosheet device comprising a first top source/drain and a second top source/drain,
wherein at least one of
the middle dielectric isolation region comprises at least one embedded stressor mechanically coupled to at least one of the bottom nanosheet device and the top nanosheet device, wherein the at least one embedded stressor imparts an embedded stressor originated stress in at least one of the bottom nanosheet device and the top nanosheet device that imparts an embedded stressor originated force against at least one of the bottom nanosheet device and the top nanosheet device, and
at least one of the bottom nanosheet device and the top nanosheet device comprise at least one interlayer originated stress that imparts at least one interlayer originated force against at least one of the bottom nanosheet device and the top nanosheet device.

2. The vertically stacked 3D nanosheet field effect transistor component of claim 1, wherein at least one of the embedded stressor originated stress and the at least one interlayer stressor originated stress comprise at least one of a compressive stress that boosts NFET device performance and a tensile stress that boosts PFET device performance.

3. The vertically stacked 3D nanosheet field effect transistor component of claim 1, wherein the first bottom source/drain comprises a first bottom epitaxy deposited source/drain, wherein the second bottom source/drain comprises a second bottom epitaxy deposited source/drain, wherein the first top source/drain comprises a first top epitaxy deposited source/drain, wherein the second top source/drain comprises a second top epitaxy deposited source/drain.

4. The vertically stacked 3D nanosheet field effect transistor component of claim 1, wherein the middle dielectric isolation region coupled to at least one of the bottom nanosheet device and the top nanosheet device further comprises another embedded stressor, wherein the another embedded stressor induces another embedded stressor originated stress in at least one of the bottom nanosheet device and the top nanosheet device that imparts another embedded stressor originated device performance boost for at least one of the bottom nanosheet device and the top nanosheet device.

5. The vertically stacked 3D nanosheet field effect transistor component of claim 1,
wherein the bottom nanosheet device comprises a bottom plurality of silicon nanosheet channels and the top nanosheet device comprises a top plurality of silicon nanosheet channels, and
wherein the at least one interlayer originated stress is imparted by at least one sacrificial interlayer stressor located in at least one of the bottom plurality of silicon nanosheet channels and the top plurality of silicon nanosheet channels.

6. The vertically stacked 3D nanosheet field effect transistor component of claim 1,
wherein the bottom nanosheet device comprises at least one sacrificial interlayer stressor that induces the at least one interlayer stressor originated stress in the bottom nanosheet device that imparts the interlayer stressor originated device performance boost for the bottom nanosheet device, and
wherein the top nanosheet device further comprises at least another sacrificial interlayer stressor that induces another at least one interlayer stressor originated stress in the top nanosheet device that imparts another interlayer stressor originated device performance boost for the top nanosheet device.

7. The vertically stacked 3D nanosheet field effect transistor component of claim 6,
wherein the interlayer stressor originated stress in the bottom nanosheet device is compressive stress to boost NFET device performance, and
wherein the another interlayer stressor originated stress in the top nanosheet device is tensile stress to boost PFET device performance.

8. The vertically stacked 3D nanosheet field effect transistor component of claim 7,
wherein the interlayer stressor originated stress in the bottom nanosheet device is imparted by at least one sacrificial stressed nanosheet interlayer comprising a first material located between at least two nanosheets of the bottom nanosheet device, and
wherein the another interlayer stressor originated stress in the top nanosheet device is imparted by at least one another sacrificial stressed nanosheet interlayer comprising a second material that is different than the first material, the at least one another sacrificial stressed nanosheet interlayer located between at least two nanosheets of the top nanosheet device.

9. A method of forming a vertically stacked 3D nanosheet field effect transistor component, the method comprising:
providing a vertically stacked nanosheet component comprising
a bottom nanosheet component;
a middle dielectric isolation region coupled to the bottom nanosheet component; and
a top nanosheet component coupled to the middle dielectric isolation region;
depositing an oxide/SiN liner on at least a portion of the middle dielectric isolation region;
releasing selectively at least a portion of the middle dielectric isolation region to define an embedded stressor region;
stripping the oxide/SiN liner; and
depositing an embedded stressor material at least within the embedded stressor region using atomic layer depositing.

10. The method of claim 9, further comprising:
depositing a spin on glass coating;
chemical mechanical polishing the spin on glass coating; and
recessing the spin on glass coating.

11. The method of claim 10, further comprising:
stripping embedded stressor material from sidewalls of the top nanosheet component.

12. The method of claim 11, further comprising:
depositing a low-k spacer material on at least sidewalls of the top nanosheet component; and
reactive ion etching the low-k spacer material.

13. The method of claim 12, further comprising:
depositing another spin on glass coating;
chemical mechanical polishing the another spin on glass coating; and
recessing the another spin on glass coating.

14. The method of claim 13, further comprising:
depositing oxide spacers; and
reactive ion etching.

15. A method of forming a vertically stacked 3D nanosheet field effect transistor component, the method comprising:
providing a vertically stacked nanosheet component comprising:
a bottom nanosheet component;
a middle dielectric isolation region coupled to the bottom nanosheet component; and
a top nanosheet component coupled to the middle dielectric isolation region;
forming at least two recesses that extend through the top nanosheet component, the middle dielectric isolation region and the bottom nanosheet component;
depositing a spin on glass coating;
chemical mechanical polishing the spin on glass coating;
etching the spin on glass coating back to form at least two recesses that extend down to beneath a top of the middle dielectric isolation region;
depositing an oxide liner on the at least two recesses that extend down to beneath a top of the middle dielectric isolation region to protect the top nanosheet component;
releasing at least a portion of the bottom nanosheet component to define at least one bottom interlayer stressor region;
depositing at least one bottom sacrificial stressed dielectric to plug the at least one bottom interlayer stressor region;
etching back the at least one bottom sacrificial stressed dielectric;
etching away the oxide liner;
releasing at least a portion of the top nanosheet component to define at least one top interlayer stressor region;
depositing at least one top sacrificial stressed dielectric to plug the at least one top interlayer stressor region;
etching back the at least one top sacrificial stressed dielectric;
etching to indent both the at least one bottom sacrificial stressed dielectric and the at least one top sacrificial stressed dielectric;
depositing at least one bottom inner spacer adjacent the at least one bottom sacrificial stressed dielectric and depositing at least one top inner spacer adjacent the at least one top sacrificial stressed dielectric;
depositing at least two bottom source/drains adjacent the at least one bottom inner spacer and depositing at least two bottom dielectric plugs adjacent tops of the at least two bottom source/drains;
depositing at least two top source/drains adjacent the at least one top inner spacer and depositing at least two top dielectric plug adjacent tops of the at least two top source/drains;
forming at least two vias through the top nanosheet component, through the middle dielectric isolation region, and to a bottom of the bottom nanosheet component;
removing both the at least one top sacrificial stressed dielectric and the at least one bottom sacrificial stressed dielectric, using the at least two vias; and
depositing a high K dielectric layer.

16. The method of claim 15, further comprising depositing a work function metal in the at least two vias.

17. The method of claim 16, further comprising depositing gate metallization.

18. The method of claim 16, wherein depositing at least one bottom sacrificial stressed dielectric to plug the at least one bottom interlayer stressor region comprises plasma enhanced atomic layer deposition and depositing at least one top sacrificial stressed dielectric to plug the at least one top interlayer stressor region comprises plasma enhanced atomic layer deposition.

19. The method of claim 16,
wherein depositing at least one bottom sacrificial stressed dielectric to plug the at least one bottom interlayer stressor region comprises depositing a first material, and
wherein depositing at least one top sacrificial stressed dielectric to plug the at least one top interlayer stressor region comprises depositing a second material that is different from the first material.

20. The method of claim 16, wherein the at least two bottom source/drains are epitaxy deposited source/drains and the at least two top source/drains are epitaxy deposited source/drains.
